(19) United States
(12) Patent Application Publication
(10) Pub. No.: US 2022/0206390 A1
(43) Pub. Date: Jun. 30, 2022

(54) PHOTOSENSITIVE COMPOSITION, TRANSFER FILM, CURED FILM, LAMINATE, TOUCH PANEL, METHOD FOR PRODUCING POLYMER, AND METHOD FOR PRODUCING PHOTOSENSITIVE COMPOSITION

(71) Applicant: FUJIFILM CORPORATION, Tokyo (JP)

(72) Inventor: Kunihiko KODAMA, Shizuoka (JP)

(21) Appl. No.: 17/697,969

(22) Filed: Mar. 18, 2022

Related U.S. Application Data
(63) Continuation of application No. PCT/JP2020/033065, filed on Sep. 1, 2020.

(30) Foreign Application Priority Data
Sep. 27, 2019 (JP) 2019-176902

(51) Int. Cl. G03F 7/09; G03F 7/028; C08F 265/06; B32B 27/08; B32B 27/36; B32B 7/06

(52) U.S. Cl. CPC G03F 7/093; G03F 7/028; C08F 265/06; B32B 27/08; B32B 2457/208; B32B 7/06; B32B 2255/26; B32B 2255/10; B32B 27/36

(57) ABSTRACT

Provided are a photosensitive composition including a polymer having a polymerizable functional group in a side chain and an ammonium compound including an ammonium cation and a carboxylate anion; a transfer film; a cured film; a laminate; a touch panel; a method for producing a polymer; and a method for producing a photosensitive composition.

### CROSS-REFERENCE TO RELATED APPLICATIONS

This application is a continuation application of International Application No. PCT/JP2020/033065, filed Sep. 1, 2020, the disclosure of which is incorporated herein by reference in its entirety. Further, this application claims priority from Japanese Patent Application No. 2019-176902, filed Sep. 27, 2019, the disclosure of which is incorporated herein by reference in its entirety.

### BACKGROUND OF THE INVENTION

### 1. Field of the Invention

The present disclosure relates to a photosensitive composition, a transfer film, a cured film, a laminate, a touch panel, a method for producing a polymer, and a method for producing a photosensitive composition.

### 2. Description of the Related Art

Photosensitive compositions (for example, negative tone photosensitive compositions that are cured by light) have been widely utilized as, for example, a protective film in an etching treatment and a protective film for a conductive layer (for example, metal wiring).

For example, JP2013-148602A discloses a negative tone photosensitive resin composition including: (A) a radically polymerizable compound; (B) a radically polymerizable photopolymerization initiator; (C) an alkali-soluble resin; and (D) a phosphoric acid ester having an ethylenically unsaturated group.

For example, JP2013-527937A discloses a photosensitive resist composition including: (A) a polyacrylate monomer; (B) a binder including an alkali-soluble copolymer having a side chain including an ethylenically unsaturated bond; (C) a pigment; and (D) a photopolymerization initiator.

For example, JP2002-341530A discloses a negative tone water-soluble photosensitive resin composition containing: (A) a water-soluble polymer including a structural unit having a carboxyl group in a side chain and a structural unit having at least one ethylenic double bond in a side chain; (B) a (meth)acrylamidomethylene group-containing compound; and (C) a photopolymerization initiator.

### SUMMARY OF THE INVENTION

However, in a case where a conventional photosensitive composition is used by bringing the composition into contact with a conductive layer, the resistance value of the conductive layer may increase. There is a possibility that a change in the resistance value as described above may interfere with normal operation of, for example, a device such as a touch panel.

The present disclosure has been made in view of the above-described circumstances.

An aspect of the present disclosure is intended to provide a photosensitive composition capable of suppressing an increase in the resistance value of a conductive layer.

Another aspect of the present disclosure is intended to provide a transfer film capable of suppressing an increase in the resistance value of a conductive layer.

Another aspect of the present disclosure is intended to provide a cured film capable of suppressing an increase in the resistance value of a conductive layer.

Another aspect of the present disclosure is intended to provide a laminate capable of suppressing an increase in the resistance value of a conductive layer.

Another aspect of the present disclosure is intended to provide a touch panel capable of suppressing an increase in the resistance value of a conductive layer.

Another aspect of the present disclosure is intended to provide a method for producing a polymer that is adequate for utilization in a photosensitive composition capable of suppressing an increase in the resistance value of a conductive layer.

Another aspect of the present disclosure is intended to provide a method for producing a photosensitive composition capable of suppressing an increase in the resistance value of a conductive layer.

The present disclosure includes the following aspects.

<1> A photosensitive composition comprising: a polymer having a polymerizable functional group in a side chain; and an ammonium compound containing an ammonium cation and a carboxylate anion.

<2> The photosensitive composition according to claim 1, in which the photosensitive composition is a negative tone photosensitive composition.

<3> The photosensitive composition according to <1> or <2>, in which a content of the ammonium compound is 0.01% by mass to 5% by mass with respect to a total solid content mass of the photosensitive composition.

<4> The photosensitive composition according to any one of <1> to <3>, in which the ammonium compound is at least one ammonium compound selected from the group consisting of an ammonium carboxylic acid salt and a zwitterion having an ammonium group and a carboxylate group in a molecule.

<5> The photosensitive composition according to any one of <1> to <3>, in which the ammonium compound is an ammonium carboxylic acid salt.

<6> The photosensitive composition according to <5>, in which the ammonium carboxylic acid salt is a tetraalkylammonium carboxylic acid salt.

<7> The photosensitive composition according to any one of <1> to <3>, in which the ammonium compound is a zwitterion having an ammonium group and a carboxylate group in a molecule.

<8> The photosensitive composition according to <7>, in which the zwitterion is a zwitterion having a trialkylammonium group and a carboxylate group in the molecule.

<9> The photosensitive composition according to any one of <1> to <8>, in which the polymer has at least one group selected from the group consisting of an aliphatic cyclic hydrocarbon group and an aromatic group.

<10> The photosensitive composition according to any one of <1> to <9>, in which the polymer is a polymer obtained by reacting a polymer having a carboxy group with a polymerizable compound having a cyclic ether group in the presence of an ammonium compound containing an ammonium cation and a carboxylate anion.

<11> The photosensitive composition according to any one of <1> to <10>, further comprising a polymerizable monomer.

<12> The photosensitive composition according to any one of <1> to <11>, further comprising a photopolymerization initiator.

<13> The photosensitive composition according to any one of <1> to <12>, in which the photosensitive composition is used for a protective film of a silver conductive material.

<14> A transfer film comprising: a temporary support; and a layer containing the photosensitive composition according to any one of <1> to <13>.

<15> A cured film of the photosensitive composition according to any one of <1> to <13>.

<16> A laminate comprising: a substrate; a layer containing a silver nanowire; and a cured film of the photosensitive composition according to any one of <1> to <13>.

<17> A touch panel comprising the laminate according to <16>.

<18> A method for producing a polymer having a polymerizable functional group in a side chain, the method comprising: a step of reacting a polymer having a carboxy group with a polymerizable compound having a cyclic ether group in the presence of an ammonium compound containing an ammonium cation and a carboxylate anion, to form a polymer having a polymerizable functional group in a side chain.

<19> A method for producing the photosensitive composition according to any one of <1> to <13>, the method comprising: a step of reacting a polymer having a carboxy group with a polymerizable compound having a cyclic ether group in the presence of an ammonium compound containing an ammonium cation and a carboxylate anion, to form the polymer having a polymerizable functional group in a side chain.

According to an aspect of the present disclosure, a photosensitive composition capable of suppressing an increase in the resistance value of a conductive layer can be provided.

According to another aspect of the present disclosure, a transfer film capable of suppressing an increase in the resistance value of a conductive layer can be provided.

According to another aspect of the present disclosure, a cured film capable of suppressing an increase in the resistance value of a conductive layer can be provided.

According to another aspect of the present disclosure, a laminate capable of suppressing an increase in the resistance value of a conductive layer can be provided.

According to another aspect of the present disclosure, a touch panel capable of suppressing an increase in the resistance value of a conductive layer can be provided.

According to another aspect of the present disclosure, a method for producing a polymer that is adequate for utilization in a photosensitive composition capable of suppressing an increase in the resistance value of a conductive layer, can be provided.

According to another aspect of the present disclosure, a method for producing a photosensitive composition capable of suppressing an increase in the resistance value of a conductive layer can be provided.

### DESCRIPTION OF THE PREFERRED EMBODIMENTS

Hereinafter, embodiments of the present disclosure will be described in detail. The present disclosure is not at all limited to the following exemplary embodiments and can be carried out with appropriate modifications within the scope of the purpose of the present disclosure.

In the present disclosure, a numerical value range represented using the term “to” means a range including the numerical values described before and after “to” as the lower limit value and the upper limit value. With regard to numerical value ranges described stepwise in the present disclosure, the upper limit value or the lower limit value described in a certain numerical value range may be replaced with the upper limit value or the lower limit value of another numerical value range described stepwise. Furthermore, in the numerical value ranges described in the present disclosure, the upper limit value or the lower limit value described in a certain numerical value range may be replaced with a value shown in the Examples.

In the present disclosure, “(meth)acryl” means both or any one of acryl and methacryl, “(meth)acrylate” means both or any one of acrylate and methacrylate, and “(meth)acryloxy” means both or any one of acryloxy and methacryloxy.

In the present disclosure, unless particularly stated otherwise, the amount of each component in the composition means, in a case where there are a plurality of substances corresponding to each component in the composition, the total amount of a plurality of substances present in the composition.

In the present disclosure, the term “step” includes not only an independent step but also a step that is not so clearly distinguishable from other steps, as long as the predetermined purpose of the step is achieved.

With regard to the notation of a group (atomic group) according to the present disclosure, a notation that does not describe substitution or unsubstitution includes a group (atomic group) not having a substituent as well as a group (atomic group) having a substituent. For example, the term “alkyl group” includes not only an alkyl group having no substituent (unsubstituted alkyl group) but also an alkyl group having a substituent (substituted alkyl group).

In the present disclosure, the units “% by mass” and “% by weight” are synonymous, and the units “parts by mass” and “parts by weight” are synonymous.

In the present disclosure, the term “main chain” means a relatively longest bonded chain in a molecule of a polymer compound constituting a resin.

In the present disclosure, the term “side chain” means an atomic group branched from the main chain.

In the present disclosure, a combination of two or more preferred aspects is a more preferred aspect.

In the present disclosure, a chemical structural formula may be described as a simplified structural formula omitting hydrogen atoms.

In the present disclosure, unless particularly stated otherwise, the proportion of a structural unit in a resin represents molar proportion.

In the present disclosure, unless particularly stated otherwise, the molecular weight in a case where there is a molecular weight distribution represents a weight-average molecular weight (Mw).

Unless particularly stated otherwise, the weight-average molecular weight (Mw) and the number-average molecular weight (Mn) in the present disclosure are molecular weights detected by means of a gel permeation chromatography (GPC) analyzer using columns of TSKgel GMHxL, TSKgel G4000HxL, and TSKgel G2000HxL (all are trade names manufactured by Tosoh Corporation) and using tetrahydrofuran (THF) as a solvent, and by means of a differential refractometer, and converted using polystyrenes as standard substances.

In the present disclosure, the term “solid content” means components obtained by removing the solvent from the entire composition of the composition.

<Photosensitive Composition>

The photosensitive composition according to the present disclosure includes a polymer having a polymerizable functional group in a side chain (hereinafter, may be referred to as “specific polymer”), and an ammonium compound including ammonium cation and a carboxylate anion (hereinafter, may be referred to as “specific ammonium compound”).

By having the above-described configuration, the photosensitive composition according to the present disclosure can suppress an increase in the resistance value of a conductive layer. The reason why the photosensitive composition according to the present disclosure provides the above-described effect is not clearly known; however, the reason is presumed as follows. In conventional methods for producing a photosensitive composition, an ammonium compound such as ammonium halide may be used as an additive or as a catalyst for a reaction for introducing a polymerizable functional group into a polymer. In a case where an ammonium compound such as ammonium halide is included in the photosensitive composition, there is a possibility that the ammonium compound may cause corrosion of the metal included in the conductive layer in a case of bringing the photosensitive composition into contact with a conductive layer. Corrosion of the metal included in the conductive layer tends to occur in a case where an ammonium compound including a halogen is used. On the other hand, it is considered that since the specific ammonium compound applied to the photosensitive composition according to the present disclosure includes an ammonium cation and a carboxylate anion, corrosion of the metal included in the conductive layer can be suppressed as compared with an ammonium compound such as ammonium halide. Therefore, according to the photosensitive composition according to the present disclosure, it is possible to suppress an increase in the resistance value of a conductive layer.

The photosensitive composition according to the present disclosure may be a positive tone photosensitive composition or a negative tone photosensitive composition. The photosensitive composition according to the present disclosure is preferably a negative tone photosensitive composition, from the viewpoint of suitability at the time of being utilized as a protective film.

<<Specific Polymer>>

The photosensitive composition according to the present disclosure includes a polymer having a polymerizable functional group in a side chain (that is, a specific polymer). As the photosensitive composition according to the present disclosure includes the above-described specific polymer, the durability of a cured product obtainable by curing the photosensitive composition can be enhanced.

As the polymerizable functional group, known polymerizable functional groups can be utilized without limitation. The polymerizable functional group is preferably a functional group including an ethylenically unsaturated double bond. Examples of the functional group including an ethylenically unsaturated double bond include an acryloyl group and a methacryloyl group. Among the above, the polymerizable functional group is preferably an acryloyl group or a methacryloyl group. The acryloyl group may be an acryloyloxy group. The methacryloyl group may be a methacryloyloxy group.

The specific polymer may have one kind of polymerizable functional group alone or may have two or more kinds of polymerizable functional groups.

The polymerizable functional group disposed in a side chain of the specific polymer is usually introduced into the specific polymer as an atomic group constituting a structural unit of the specific polymer. In the specific polymer, the structure of the structural unit having a polymerizable functional group is not limited. From the viewpoint of curability and manufacturability, it is preferable that the specific polymer has a structural unit derived from a (meth)acrylate compound having a polymerizable functional group, and it is more preferable that the specific polymer has a structural unit represented by the following Formula (1).

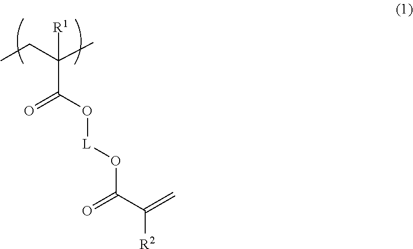

In Formula (1), R¹ represents a hydrogen atom or an alkyl group having 1 to 3 carbon atoms; R² represents a hydrogen atom or an alkyl group having 1 to 3 carbon atoms; and L represents a divalent linking group.

In Formula (1), the alkyl group represented by R¹ may be a linear alkyl group or a branched alkyl group. In Formula (1), R¹ is preferably a hydrogen atom or a methyl group, and more preferably a methyl group.

In Formula (1), the alkyl group represented by R² may be a linear alkyl group or a branched alkyl group. In Formula (1), R² is preferably a hydrogen atom or a methyl group, and more preferably a methyl group.

In Formula (1), the divalent linking group represented by L may be, for example, an alkylene group or an arylene group. The alkylene group may be a linear alkylene group or a branched alkylene group. Furthermore, the alkylene group may be substituted with a substituent (for example, a hydroxy group). In Formula (1), the divalent linking group represented by L is preferably an alkylene group, more preferably an alkylene group having 1 to 6 carbon atoms, and even more preferably an alkylene group having 2 to 4 carbon atoms.

The structural unit represented by the above-described Formula (1) is preferably a structural unit represented by the following Formula (2).

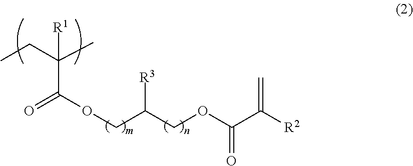

In Formula (2), R¹ represents a hydrogen atom or an alkyl group having 1 to 3 carbon atoms; R² represents a hydrogen atom or an alkyl group having 1 to 3 carbon atoms; R³ represents a hydrogen atom, an alkyl group having 1 to 3 carbon atoms, or a hydroxy group; m represents an integer of 0 to 3; and n represents an integer of 1 to 3.

R¹ in Formula (2) is synonymous with R¹ in Formula (1), and the same also applies to preferred aspects.

R² in Formula (2) is synonymous with R² in Formula (1), and the same also applies to preferred aspects.

In Formula (2), the alkyl group represented by R³ may be a linear alkyl group or a branched alkyl group. In Formula (2), R³ is preferably a hydroxy group.

In Formula (2), m is preferably 1 or 2, and more preferably 1.

In Formula (2), n is preferably 1 or 2, and more preferably 1.

The content of the structural unit having a polymerizable functional group is preferably 1 mol % to 80 mol %, more preferably 5 mol % to 70 mol %, and particularly preferably 10 mol % to 50 mol %, with respect to the total amount of the specific polymer. As the content of the structural unit having a polymerizable functional group is in the above-described range, the durability of a cured product obtainable by curing the photosensitive composition can be enhanced.

The specific polymer may have a group other than the polymerizable functional group (hereinafter, referred to as “other group”). Examples of the other group include a chain-like hydrocarbon group, an aliphatic cyclic hydrocarbon group, an aromatic group, and an alkali-soluble group.

It is preferable that the specific polymer has at least one group selected from the group consisting of an aliphatic cyclic hydrocarbon group and an aromatic group. As the specific polymer has at least one group selected from the group consisting of an aliphatic cyclic hydrocarbon group and an aromatic group, water vapor permeation of a cured film can be suppressed, and in a case where the cured film is used as, for example, a touch sensor wiring protective film, reliability is enhanced.

The aliphatic cyclic hydrocarbon group may be a monocyclic group or a polycyclic group and is preferably an aliphatic cyclic hydrocarbon group having 5 to 20 carbon atoms, and more preferably an aliphatic cyclic hydrocarbon group having 5 to 12 carbon atoms. Examples of the aliphatic cyclic hydrocarbon group include a cyclopentyl group, a cyclohexyl group, a 4-tert-butylcyclohexyl group, an isoboronyl group, an adamantyl group, a dicyclopentenyl group, and a dicyclopentanyl group. Among those described above, the aliphatic cyclic hydrocarbon group is preferably a cyclohexyl group or a dicyclopentanyl group, and more preferably a dicyclopentanyl group.

The aromatic ring in the aromatic group may be a monocyclic ring or a fused ring. The aromatic group is preferably an aromatic group having 6 to 20 carbon atoms, and more preferably an aromatic group having 6 to 12 carbon atoms. Examples of the aromatic group include a phenyl group, a tolyl group, a tert-butoxyphenyl group, a tert-butylphenyl group, and a naphthyl group. Among those described above, the aromatic group is preferably phenyl.

At least one group selected from the group consisting of an aliphatic cyclic hydrocarbon group and an aromatic group is usually introduced into the specific polymer as an atomic group constituting a structural unit of the specific polymer.

Examples of the structural unit having an aliphatic cyclic hydrocarbon group include structural units derived from cyclohexyl (meth)acrylate, cyclopentyl (meth)acrylate, dicyclopentanyl (meth)acrylate, dicyclopentenyl (meth)acrylate, dicyclopentanyl oxyethyl (meth)acrylate, dicyclopentenyl oxyethyl (meth)acrylate, isoboronyl (meth)acrylate, or adamantyl (meth)acrylate, and a structural unit derived from cyclohexyl (meth)acrylate or dicyclopentanyl (meth)acrylate is preferred.

Examples of the structural unit having an aromatic group include structural units derived from styrene, α-methylstyrene, t-butylstyrene, benzyl (meth)acrylate, or phenoxyethyl (meth)acrylate, and a structural unit derived from styrene or benzyl (meth)acrylate is preferable.

The content of the structural unit having at least one group selected from the group consisting of an aliphatic cyclic hydrocarbon group and an aromatic group is preferably 1 mol % to 80 mol %, more preferably 5 mol % to 70 mol %, and particularly preferably 10 mol % to 65 mol %, with respect to the total amount of the specific polymer.

It is preferable that the specific polymer has an alkali-soluble group, and it is more preferable that the specific polymer has a carboxy group. As the specific polymer has a carboxy group, the developability of the photosensitive composition in photolithography can be enhanced.

The carboxy group is usually introduced into the specific polymer as an atomic group constituting a structural unit of the specific polymer.

Examples of the structural unit having a carboxy group include structural units derived from (meth)acrylic acid, 2-(meth)acryloyloxyethyl succinic acid, or 4-vinylbenzoic acid, and a structural unit derived from (meth)acrylic acid is preferred.

The content of the structural unit having a carboxy group is preferably 5 mol % to 50 mol %, more preferably 10 mol % to 40 mol %, and particularly preferably 15 mol % to 30 mol %, with respect to the total amount of the specific polymer.

In some aspects, the specific polymer is preferably a polymer obtained by reacting a polymer having a carboxy group with a polymerizable compound having a cyclic ether group in the presence of an ammonium compound including an ammonium cation and a carboxylate anion (that is, specific ammonium compound). In the specific polymer obtainable by reacting a polymer having a carboxy group with a polymerizable compound having a cyclic ether group, a polymerizable functional group is introduced into a side chain by esterification of the carboxy group accompanied by ring-opening of the cyclic ether. The polymerizable functional group is derived from the polymerizable functional group included in the polymerizable compound having a cyclic ether group. The details of the above-described reaction will be described in the following section “Method for producing specific polymer”.

A preferred structure of the specific polymer is shown below. However, in the following structure, the content ratio of each structural unit of the polymer and the molecular weight of the polymer may be determined according to the purpose.

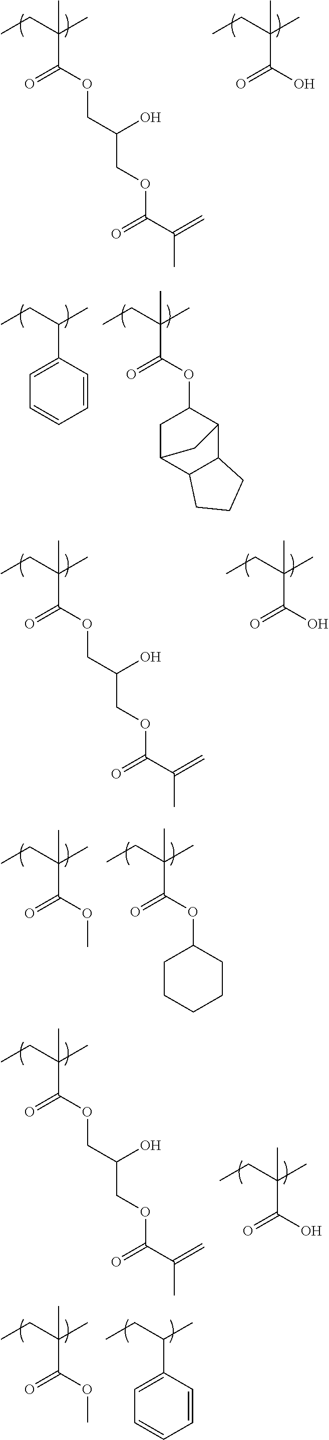

From the viewpoint of enhancing developability, the acid value of the specific polymer is preferably 60 mgKOH/g or more, and more preferably 70 mgKOH/g or more. From the viewpoint of alkali resistance, the acid value of the specific polymer is preferably 200 mgKOH/g or less, and more preferably 130 mgKOH/g or less. The acid value of the specific polymer is measured according to the method described in JIS K 0070:1992.

From the viewpoint of curability and developability, the weight-average molecular weight of the specific polymer is preferably 3,000 to 100,000, more preferably 5,000 to 50,000, and particularly preferably 8,000 to 30,000. The weight-average molecular weight of the specific polymer is a weight-average molecular weight determined by gel permeation chromatography (GPC) and calculated relative to polystyrene standards.

The photosensitive composition according to the present disclosure may include one kind of specific polymer alone or may include two or more kinds of specific polymers.

The content of the specific polymer is preferably 10% by mass to 95% by mass, more preferably 20% by mass to 80% by mass, and particularly preferably 30% by mass to 70% by mass, with respect to the total solid content mass of the photosensitive composition. As the content of the specific polymer is in the above-described range, durability of a cured product obtainable by curing the photosensitive composition can be enhanced.

<<Residual Monomer>>

From the viewpoints of patterning properties and reliability, the content of residual monomer of each structural unit of the specific polymer is preferably 5,000 ppm by mass or less, more preferably 2,000 ppm by mass or less, and even more preferably 500 ppm by mass or less, with respect to the total mass of the specific polymer. The lower limit is not particularly limited; however, the lower limit is preferably 1 ppm by mass or more, and more preferably 10 ppm by mass or more.

From the viewpoints of patterning properties and reliability, the content of residual monomer of each structural unit of the specific polymer is preferably 3,000 ppm by mass or less, more preferably 600 ppm by mass or less, and even more preferably 100 ppm by mass or less, with respect to the total solid content mass of the photosensitive composition. The lower limit is not particularly limited; however, the lower limit is preferably 0.1 ppm by mass or more, and more preferably 1 ppm by mass or more.

It is preferable that the content of residual monomers of the monomers used at the time of synthesizing the specific polymer by a polymer reaction is also adjusted to the above-described range. For example, in a case where a polymer having a polymerizable functional group in a side chain (that is, specific polymer) is synthesized by reacting a polymer having a carboxy group with a polymerizable compound having a cyclic ether group, it is preferable that the content of the polymerizable compound having a cyclic ether group is adjusted to the above-described range.

The content of the residual monomers can be measured by a known method such as liquid chromatography or gas chromatography.

[Method for Producing Specific Polymer]

A method for producing the specific polymer is not limited. Regarding the method for producing the specific polymer, for example, a method of producing a polymer having no polymerizable functional group (hereinafter, may be referred to as “precursor polymer”) and then introducing a polymerizable functional group into a side chain of the precursor polymer, may be mentioned.

It is preferable that the method for producing the specific polymer is a method of introducing a polymerizable functional group into a side chain of the precursor polymer. Specifically, it is preferable that the method for producing the specific polymer includes a step of reacting a polymer having a carboxy group with a polymerizable compound having a cyclic ether group in the presence of an ammonium compound including an ammonium cation and a carboxylate anion (that is, specific ammonium compound) to form a polymer having a polymerizable functional group in a side chain (that is, specific polymer) (hereinafter, may be referred to as “esterification step”). As the method for producing the specific polymer includes the above-described esterification step, a specific polymer adequate for utilization in a photosensitive composition capable of suppressing an increase in the resistance value of a conductive layer, can be produced.

The polymerizable compound having a cyclic ether group has a polymerizable functional group as will be described later. In the esterification step, it is thought that as a polymer having a carboxy group is reacted with a polymerizable compound having a cyclic ether group, the carboxy group is esterified by the polymerizable compound having a cyclic ether group through ring-opening of the cyclic ether. By undergoing esterification of the carboxy group as described above, a polymerizable functional group is introduced into a side chain of the polymer. In the esterification step, all or some of the carboxy groups may be esterified.

In the esterification step, the ammonium compound including an ammonium cation and a carboxylate anion (that is, specific ammonium compound) acts as a catalyst. The details of the ammonium compound including an ammonium cation and a carboxylate anion will be described in the following section “Specific ammonium compound”.

The amount of addition of the specific ammonium compound in the esterification step is preferably 0.01% by mass to 10% by mass, more preferably 0.05% by mass to 5% by mass, and particularly preferably 0.1% by mass to 3% by mass, with respect to the sum of the total mass of the polymer having a carboxy group and the total mass of the polymerizable compound having a cyclic ether group.

A polymer having a carboxy group can be produced by, for example, polymerizing a monomer including a carboxy group. Examples of the monomer including a carboxy group include (meth)acrylic acid, 2-(meth)acryloyloxyethyl succinic acid, and 4-vinylbenzoic acid, and (meth) acrylic acid is preferred. Regarding the method for polymerizing the monomer including a carboxy group, a known method can be utilized without limitation.

The polymer having a carboxy group is not limited to the case where the polymer is a homopolymer of a monomer including a carboxy group, and may be a copolymer of a monomer including a carboxy group and another monomer. For example, by using a monomer having a specific group (for example, an aliphatic cyclic hydrocarbon group or an aromatic group) as the other monomer, the specific group can be introduced into the specific polymer. Examples of the other monomer include a monomer having an aliphatic cyclic hydrocarbon group and a monomer having an aromatic group.

Examples of the aliphatic cyclic hydrocarbon group in the monomer include the aliphatic hydrocarbon groups for the specific polymer described above, and preferred aspects are also similar.

Specifically, examples of the monomer having an aliphatic cyclic hydrocarbon group include monomers that form the above-described structural unit having an aliphatic cyclic hydrocarbon group, and preferred aspects are also similar.

Examples of the aromatic group in the monomer include the aromatic groups for the specific polymer described above, and preferred aspects are also similar.

Specifically, examples of the monomer having an aromatic group include monomers that form the above-described structural unit having an aromatic group, and preferred aspects are also similar.

The number of ring members of the cyclic ether in the cyclic ether group is preferably 3 to 6, and more preferably 3, from the viewpoint of reactivity.

From the viewpoint of reactivity, the cyclic ether group is preferably an epoxy group or an oxetanyl group, and more preferably an epoxy group.

The polymerizable compound having a cyclic ether group has a polymerizable functional group in addition to the cyclic ether group. The polymerizable functional group is as described in the above-described section “Specific polymer”, and preferred aspects are also similar.

Examples of the polymerizable compound having a cyclic ether group include glycidyl (meth)acrylate, 3,4-epoxycyclohexylmethyl (meth)acrylate, and (3-ethyloxetan-3-yl)methyl (meth)acrylate, and glycidyl (meth)acrylate is preferred.

In the esterification step, a polymer having a carboxy group may be reacted with a polymerizable compound having a cyclic ether group, in the presence of a solvent as necessary. As the solvent, a known solvent can be utilized without limitation. Examples of the solvent include ethylene glycol monoalkyl ether-based solvents, ethylene glycol dialkyl ether-based solvents, ethylene glycol monoalkyl ether acetate-based solvents, propylene glycol monoalkyl ether-based solvents, propylene glycol dialkyl ether-based solvents, propylene glycol monoalkyl ether acetate-based solvents, diethylene glycol dialkyl ether-based solvents, diethylene glycol monoalkyl ether acetate-based solvents, dipropylene glycol monoalkyl ether-based solvents, dipropylene glycol dialkyl ether-based solvents, dipropylene glycol monoalkyl ether acetate-based solvents, ester-based solvents, ketone-based solvents (preferably, methyl ethyl ketone, methyl isobutyl ketone, cyclohexanone, and 2-heptanone), amide-based solvents (preferably dimethylformamide, dimethylacetamide, N-methylpyrrolidone, and N-ethylpyrrolidone), and lactone-based solvents.

It is preferable that the solvent includes at least one solvent selected from the group consisting of propylene glycol monoalkyl ether-based solvents, ethylene glycol monoalkyl ether acetate-based solvents, propylene glycol monoalkyl ether acetate-based solvents, diethylene glycol monoalkyl ether acetate-based solvents, and dipropylene glycol monoalkyl ether acetate-based solvents; it is more preferable that the solvent includes at least one solvent selected from the group consisting of propylene glycol monoalkyl ether-based solvents and propylene glycol monoalkyl ether acetate-based solvents; and it is particularly preferable that the solvent includes at least one selected from propylene glycol monomethyl ether or propylene glycol monomethyl ether acetate.

The reaction time in the esterification step is not limited and may be determined, for example, according to the types and amounts of raw materials. The reaction time in the esterification step is preferably 1 hour to 20 hours, and more preferably 3 hours to 10 hours.

The reaction temperature in the esterification step is not limited and may be determined, for example, according to the types and amounts of raw materials. The reaction temperature in the esterification step is preferably 50° C. to 130° C., and more preferably 80° C. to 120° C.

As an example of a method for producing the specific polymer, a reaction between a polymer having a carboxy group and glycidyl methacrylate (polymerizable compound having a cyclic ether group) will be described. Glycidyl methacrylate has an epoxy group as a cyclic ether group and a methacryloyloxy group as a polymerizable functional group. As shown in the following reaction formula, as a polymer having a carboxy group is reacted with glycidyl methacrylate in the presence of the specific ammonium compound, a polymerizable functional group (methacryloyloxy group) is introduced into a side chain of the polymer through esterification of the carboxy group. In the following reaction formula, the content ratio of each structural unit of the polymer and the molecular weight of the polymer may be determined according to the purpose.

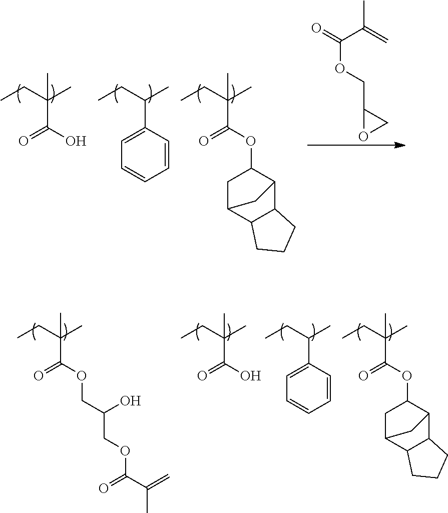

<<Specific Ammonium Compound>>

The photosensitive composition according to the present disclosure includes an ammonium compound including an ammonium cation and a carboxylate anion (that is, specific ammonium compound). As the photosensitive composition according to the present disclosure includes the above-mentioned specific ammonium compound, corrosion of a conductive layer can be suppressed, and therefore, an increase in the resistance value of the conductive layer can be suppressed.

Ammonium cation is an atomic group including a positively charged nitrogen atom. The ammonium cation may be, for example, an atomic group constituting an ion pair with a carboxylate anion in the chemical structure of the specific ammonium compound. Furthermore, the ammonium cation may be, for example, an atomic group constituting a substituent in the chemical structure of the specific ammonium compound. Examples of the ammonium cation include a primary ammonium cation, a secondary ammonium cation, a tertiary ammonium cation, and a quaternary ammonium cation. Among those described above, the ammonium cation is preferably a quaternary ammonium cation from the viewpoint of stability.

From the viewpoint of stability, the quaternary ammonium cation is preferably a tetraalkylammonium cation, more preferably a tetraalkylammonium cation with each alkyl group having 1 to 20 (preferably 1 to 4) carbon atoms, even more preferably a tetramethylammonium cation, a tetraethylammonium cation, or a tetrabutylammonium cation, and particularly preferably a tetrabutylammonium cation.

The carboxylate anion is an atomic group including “C(═O)O⁻”. The carboxylate anion may be, for example, an atomic group constituting an ion pair with an ammonium cation in the chemical structure of the specific ammonium compound. Furthermore, the carboxylate anion may be, for example, an atomic group constituting a substituent in the chemical structure of the specific ammonium compound.

Examples of the specific ammonium compound include a salt of an ammonium cation and a carboxylate anion (hereinafter referred to as “ammonium carboxylic acid salt”), and a zwitterion having an ammonium group and a carboxylate group (—C(═O)O⁻) in the molecule. From the viewpoint of suppressing an increase in the resistance value of a conductive layer, the specific ammonium compound is preferably at least one ammonium compound selected from the group consisting of an ammonium carboxylic acid salt and a Zwitterion having an ammonium group and a carboxylate group in the molecule, and more preferably an ammonium carboxylic acid salt.

From the viewpoint of stability, the ammonium cation in the ammonium carboxylic acid salt is preferably a quaternary ammonium cation. Preferred aspects of the quaternary ammonium cation are as described above.

Examples of the carboxylate anion in the ammonium carboxylic acid salt include an aliphatic carboxylate anion and an aromatic carboxylate anion. From the viewpoint of suppressing an increase in the resistance value of a conductive layer, the carboxylate anion is preferably an aliphatic carboxylate anion, and more preferably an acetate anion (CH₃COO⁻).

From the viewpoint of suppressing an increase in the resistance value of a conductive layer, the ammonium carboxylic acid salt is preferably a tetraalkylammonium carboxylic acid salt, more preferably a tetraalkylammonium acetic acid salt, even more preferably a tetraalkylammonium acetic acid salt with each alkyl group having 1 to 4 carbon atoms, particularly preferably tetramethylammonium acetic acid salt, tetraethylammonium acetic acid salt, or tetrabutylammonium acetic acid salt, and most preferably a tetrabutylammonium acetic acid salt (hereinafter, may be referred to as “tetrabutylammonium acetate”).

The ammonium group in the zwitterion is preferably a trialkylammonium group, more preferably a trialkylammonium group with each alkyl group having 1 to 4 carbon atoms, even more preferably a trimethylammonium group, a triethylammonium group, or a tributylammonium group, and particularly preferably a trimethylammonium group.

As the zwitterion, for example, a compound in which a hydrogen atom on the nitrogen atom of an amino acid is substituted by an alkyl group is preferred, and for example, betaine (chemical formula: (CH₃)₃N⁺—CH₂COO⁻, also known as: trimethylglycine or anhydrous betaine). The zwitterion is preferably betaine from the viewpoint of suppressing an increase in the resistance value of a conductive layer.

The photosensitive composition according to the present disclosure may include one kind of specific ammonium compound alone or may include two or more kinds of specific ammonium compounds.

The content of the specific ammonium compound is preferably 0.01% by mass to 5% by mass, more preferably 0.1% by mass to 4% by mass, and particularly preferably 0.2% by mass to 2% by mass, with respect to the total solid content mass of the photosensitive composition. As the content of the specific ammonium compound is in the above-described range, an increase in the resistance value of a conductive layer can be suppressed.

<<Polymerizable Monomer>>

It is preferable that the photosensitive composition according to the present disclosure includes a polymerizable monomer. As the photosensitive composition according to the present disclosure includes a polymerizable monomer, the curability of the photosensitive composition can be enhanced.

As the polymerizable monomer, known polymerizable monomers can be utilized without limitation. Examples of the polymerizable monomer include a radically polymerizable monomer and a cationically polymerizable monomer. Among those described above, the polymerizable monomer is preferably a radically polymerizable monomer, and more preferably an ethylenically unsaturated monomer. An ethylenically unsaturated monomer is a monomer having one or more ethylenically unsaturated groups. The ethylenically unsaturated group is preferably a (meth)acryloyl group. The ethylenically unsaturated monomer is preferably a (meth)acrylate compound.

The ethylenically unsaturated monomer is preferably a bifunctional or higher-functional ethylenically unsaturated monomer. A bifunctional or higher-functional ethylenically unsaturated monomer is a monomer having two or more ethylenically unsaturated groups in one molecule.

Examples of a bifunctional ethylenically unsaturated monomer include tricyclodecane dimethanol di(meth)acrylate, 1,9-nonanediol di(meth)acrylate, and 1,6-hexanediol di(meth)acrylate.

Specific examples of the bifunctional ethylenically unsaturated monomer include tricyclodecane dimethanol diacrylate (A-DCP, manufactured by Shin-Nakamura Chemical Co., Ltd.), tricyclodecane dimethanol dimethacrylate (DCP, manufactured by Shin-Nakamura Chemical Co., Ltd.), 1,9-nonanediol diacrylate (A-NOD-N, manufactured by Shin-Nakamura Chemical Co., Ltd.), 1,6-hexanediol diacrylate (A-HD-N, manufactured by Shin-Nakamura Chemical Co., Ltd.), and polytetramethylene glycol #650 diacrylate (A-PTMG-65, manufactured by Shin-Nakamura Chemical Co., Ltd.).

Examples of the trifunctional or higher-functional ethylenically unsaturated monomer include dipentaerythritol (tri/tetra/penta/hexa)(meth)acrylate, pentaerythritol (tri/tetra)(meth)acrylate, and trimethylolpropane tri(meth)acrylate, ditrimethylolpropane tetra(meth)acrylate, isocyanuric acid (meth)acrylate, and glycerin tri(meth)acrylate. Here, the term “(tri/tetra/penta/hexa)(meth)acrylate” is a concept including tri(meth)acrylate, tetra(meth)acrylate, penta(meth)acrylate, and hexa(meth)acrylate. Furthermore, the term “(tri/tetra)(meth)acrylate” is a concept including tri(meth)acrylate and tetra(meth)acrylate.

Regarding the polymerizable monomer, it is preferable to use a bifunctional ethylenically unsaturated monomer and a trifunctional or higher-functional ethylenically unsaturated monomer in combination.

From the viewpoint of curability, the content of the bifunctional ethylenically unsaturated monomer in all the polymerizable monomers is preferably 5% by mass to 80% by mass, and more preferably 10% by mass to 50% by mass, with respect to the total solid content mass of the photosensitive composition.

From the viewpoint of curability, the content of the trifunctional or higher-functional ethylenically unsaturated monomer in all the polymerizable monomers is preferably 5% by mass to 80% by mass, and more preferably 10% by mass to 50% by mass, with respect to the total solid content mass of the photosensitive composition.

The content ratio of the bifunctional ethylenically unsaturated monomer to the trifunctional or higher-functional ethylenically unsaturated monomer (bifunctional ethylenically unsaturated monomer/trifunctional or higher-functional ethylenically unsaturated monomer) is preferably 10/90 to 90/10, and more preferably 25/75 to 75/25, on a mass basis.

Regarding the combination of the bifunctional ethylenically unsaturated monomer and the trifunctional or higher-functional ethylenically unsaturated monomer, it is preferable to include an alkanediol di(meth)acrylate compound, a pentafunctional (meth)acrylate compound, and a hexafunctional (meth)acrylate compound, and it is more preferable to include 1,9-nonanediol di(meth)acrylate or 1,10-decanediol di(meth)acrylate, dipentaerythritol hexa(meth)acrylate, and dipentaerythritol penta(meth)acrylate.

The photosensitive composition according to the present disclosure may include one kind of polymerizable monomer alone or may include two or more kinds of polymerizable monomers.

In a case where the photosensitive composition according to the present disclosure includes a polymerizable monomer, from the viewpoint of curability, the content of the polymerizable monomer is preferably 5% by mass to 85% by mass, more preferably 10% by mass to 70% by mass, and particularly preferably 30% by mass to 60% by mass, with respect to the total solid content mass of the photosensitive composition.

<<Photopolymerization Initiator>>

It is preferable that the photosensitive composition according to the present disclosure includes a photopolymerization initiator. As the photosensitive composition according to the present disclosure includes a photopolymerization initiator, a curing reaction of the photosensitive composition can be accelerated.

As the photopolymerization initiator, a known photopolymerization initiator can be used without limitation. Examples of the photopolymerization initiator include a photopolymerization initiator having an oxime ester structure (hereinafter, may be referred to as “oxime-based photopolymerization initiator”), a photopolymerization initiator having an α-aminoalkylphenone structure (hereinafter, may be referred to as “α-aminoalkylphenone-based photopolymerization initiator”), a photopolymerization initiator having an α-hydroxyalkylphenone structure (hereinafter, may be referred to as “α-hydroxyalkylphenone-based polymerization initiator”), a photopolymerization initiator having an acylphosphine oxide structure (hereinafter, may be referred to as “acylphosphine oxide-based photopolymerization initiator”), and a photopolymerization initiator having an N-phenylglycine structure (hereinafter, may be referred to as “N-phenylglycine-based photopolymerization initiator”).

It is preferable that the photopolymerization initiator includes at least one photopolymerization initiator selected from the group consisting of an oxime-based photopolymerization initiator, an α-aminoalkylphenone-based photopolymerization initiator, an α-hydroxyalkylphenone-based polymerization initiator, and an N-phenylglycine-based photopolymerization initiator, and it is more preferable that the photopolymerization initiator includes at least one photopolymerization initiator selected from the group consisting of an oxime-based photopolymerization initiator, an α-aminoalkylphenone-based photopolymerization initiator, and an N-phenylglycine-based photopolymerization initiator.

Examples of the photopolymerization initiator include the photopolymerization initiators described in paragraph 0031 to paragraph 0042 of JP2011-95716A and paragraph 0064 to paragraph 0081 of JP2015-014783A.

Examples of commercially available products of the photopolymerization initiator include 1-[4-(phenylthio)phenyl]-1,2-octanedione-2-(O-benzoyloxime) (trade name: IRGACURE (registered trademark) OXE-01, manufactured by BASF SE), 1-[9-ethyl-6-(2-methylbenzoyl)-9H-carbazol-3-yl]ethanone-1-(0-acetyloxime) (trade name: IRGACURE OXE-02, manufactured by BASF SE), [8-[5-(2,4,6-trimethylphenyl)-11-(2-ethylhexyl)-11H-benzo[a]carbazoyl] [2-(2,2,3,3-tetrafluoropropoxy)phenyl]methanone-(O-acetyloxime) (trade name: IRGACURE (registered trademark) OXE-03, manufactured by BASF SE), 1-[4-[4-(2-benzofuranylcarbonyl)phenyl]thio]phenyl]-4-methyl-1-pentanone-1-(O-acetyloxime) (trade name: IRGACURE (registered trademark) OXE-04, manufactured by BASF SE), 2-(dimethylamino)-2-[(4-methylphenyl)methyl]-1-[4-(4-morpholinyl)phenyl]-1-butanone (trade name: Omnirad 379EG, manufactured by IGM Resins B.V.), 2-methyl-1-(4-methylthiophenyl)-2-morpholinopropan-1-one (trade name: Omnirad 907, manufactured by IGM Resins B.V.), 2-hydroxy-1-{4-[4-(2-hydroxy-2-methyl-propionyl)benzyl]phenyl}-2-methylpropan-1-one (trade name: Omnirad 127, manufactured by IGM Resins B.V.), 2-benzyl-2-dimethylamino-1-(4-morpholinophenyl)-1-butanone (trade name: Omnirad 369, manufactured by IGM Resins B.V.), 2-hydroxy-2-methyl-1-phenylpropan-1-one (trade name: Omnirad 1173, manufactured by IGM Resins B.V.), 1-hydroxycyclohexyl phenyl ketone (trade name: Omnirad 184, manufactured by IGM Resins B.V.), 2,2-dimethoxy-1,2-diphenylethan-1-one (trade name: Omnirad 651, manufactured by IGM Resins B.V.), 1-[4-(phenylthio)phenyl]-3-cyclopentylpropane-1,2-dione-2-(O-benzoyloxime) (trade name: TR-PBG-305, manufactured by Changzhou Tronly New Electronic Materials Co., Ltd.), 1,2-propanedione, 3-cyclohexyl-1-[9-ethyl-6-(2-furanylcarbonyl)-9H-carbazol-3-yl]2-(O-acetyloxime) (trade name: TR-PBG-326, manufactured by Changzhou Tronly New Electronic Materials Co., Ltd.), 3-cyclohexyl-1-(6-(2-(benzoyloxyimino)hexanoyl)-9-ethyl-9H-carbazol-3-yl)-propane-1,2-dione-2-(O-benzoyloxime) (trade name: TR-PBG-391, manufactured by Changzhou Tronly New Electronic Materials Co., Ltd.), and (1-(biphenyl-4-yl)-2-methyl-2-morpholinopropan-1-one (trade name: APi-307, manufactured by Shenzhen UV-ChemTech Ltd.).

The photosensitive composition according to the present disclosure may include one kind of photopolymerization initiator alone or may include two or more kinds of photopolymerization initiators. In a case where the photosensitive composition according to the present disclosure includes two or more kinds of photopolymerization initiators, from the viewpoint of curability, it is preferable that the photosensitive composition according to the present disclosure includes an oxime-based photopolymerization initiator and an α-aminoalkylphenone-based photopolymerization initiator.

In a case where the photosensitive composition according to the present disclosure includes a photopolymerization initiator, from the viewpoint of accelerating the curing reaction, the content of the photopolymerization initiator is preferably 0.01% by mass to 10% by mass, more preferably 0.05% by mass to 5% by mass, and particularly preferably 0.1% by mass to 3% by mass, with respect to the total solid content mass of the photosensitive composition.

<<Surfactant>>

The photosensitive composition according to the present disclosure may include a surfactant.

As the surfactant, a known surfactant can be utilized without limitation. Examples of the surfactant include the surfactants described in paragraph 0017 of JP4502784B and paragraph 0060 to paragraph 0071 of JP2009-237362A.

The surfactant is preferably a fluorine-based surfactant or a silicon-based surfactant. Examples of commercially available products of fluorine-based surfactants include MEGAFACE (registered trademark) F-171, F-172, F-173, F-176, F-177, F-141, F-142, F-143, F-144, F-437, F-475, F-477, F-479, F-482, F-551-A, F-552, F-554, F-555-A, F-556, F-557, F-558, F-559, F-560, F-561, F-565, F-563, F-568, F-575, F-780, EXP, MFS-330, R-41, R-41-LM, R-01, R-40, R-40-LM, RS-43, TF-1956, RS-90, R-94, RS-72-K, and DS-21 (all manufactured by DIC Corporation); FLUORAD FC430, FC431, and FC171 (all manufactured by Sumitomo 3M, Ltd.); SURFLON (registered trademark)S-382, SC-101, SC-103, SC-104, SC-105, SC-1068, SC-381, SC-383, S-393, and KH-40 (all manufactured by AGC, Inc.); PolyFox (registered trademark) PF636, PF656, PF6320, PF6520, and PF7002 (all manufactured by OMNOVA Solutions, Inc.); and FTERGENT (registered trademark) 710FM, 610FM, 601AD, 601ADH2, 602A, 215M, and 245F (all manufactured by NEOS Co., Ltd.).

Furthermore, as the fluorine-based surfactant, an acrylic compound having a molecular structure having a functional group containing a fluorine atom, in which upon applying heat, the moiety of the functional group containing a fluorine atom is cleaved so that the fluorine atom is volatilized, can also be suitably used. Examples of such a fluorine-based surfactant include the DS series of MEGAFACE (registered trademark) manufactured by DIC Corporation (see, for example, The Chemical Daily (Feb. 22, 2016) and the Nikkei Business Daily (Feb. 23, 2016)), and specifically, MEGAFACE (registered trademark) DS-21 may be mentioned.

Furthermore, as the fluorine-based surfactant, a polymer of a fluorine atom-containing vinyl ether compound having a fluorinated alkyl group or a fluorinated alkylene ether group and a hydrophilic vinyl ether compound can also be suitably used.

As the fluorine-based surfactant, a block polymer can also be used. As the fluorine-based surfactant, a fluorine-containing polymer compound including a repeating unit derived from a (meth)acrylate compound having a fluorine atom and a repeating unit derived from a (meth)acrylate compound having two or more (preferably five or more) alkyleneoxy groups (preferably ethyleneoxy groups and propyleneoxy groups) can also be suitably used.

As the fluorine-based surfactant, a fluorine-containing polymer having an ethylenically unsaturated bond-containing group in a side chain can also be used. Examples of such a fluorine-based surfactant include MEGAFACE (registered trademark) RS-101, RS-102, RS-718K, and RS-72-K (all manufactured by DIC Corporation).

Examples of a nonionic surfactant include glycerol, trimethylolpropane, trimethylolethane, and ethoxylates and propoxylates of these (for example, glycerol propoxylate and glycerol ethoxylate), polyoxyethylene lauryl ether, polyoxyethylene stearyl ether, polyoxyethylene oleyl ether, polyoxyethylene octyl phenyl ether, polyoxyethylene nonyl phenyl ether, polyethylene glycol dilaurate, polyethylene glycol distearate, sorbitan fatty acid ester; PLURONIC (registered trademark) L10, L31, L61, L62, 10R5, 17R2, and 25R2 (all manufactured by BASF SE); TETRONIC (registered trademark) 304, 701, 704, 901, 904, and 150R1 (all manufactured by BASF SE); SOLSPERSE (registered trademark) 20000 (all manufactured by Lubrizol Japan, Ltd.); NCW-101, NCW-1001, and NCW-1002 (all manufactured by FUJIFILM Wako Pure Chemical Corporation); PIONIN D-6112, D-6112-W, and D-6315 (all manufactured by Takemoto Oil & Fat Co., Ltd.); OLFINE (registered trademark) E1010, and SURFINOL 104, 400, and 440 (all manufactured by Nissin Chemical Industry Co., Ltd.).

Examples of a silicone-based surfactant include a linear polymer consisting of a siloxane bond, and a modified siloxane polymer having an organic group introduced into a side chain and/or an end. Examples of the silicone-based surfactant include DOWSIL (registered trademark) 8032 Additive, Toray Silicone DC3PA, Toray Silicone SH7PA, Toray Silicone DC11PA, Toray Silicone SH21PA, Toray Silicone SH28PA, Toray Silicone SH29PA, Toray Silicone SH30PA, and Toray Silicone SH8400 (all manufactured by DuPont Toray Specialty Materials K.K.); X-22-4952, X-22-4272, X-22-6266, KF-351A, K354L, KF-355A, KF-945, KF-640, KF-642, KF-643, X-22-6191, X-22-4515, KF-6004, KP-341, KF-6001, and KF-6002 (all manufactured by Shin-Etsu Silicone Co., Ltd.); F-4440, TSF-4300, TSF-4445, TSF-4460, and TSF-4452 (all manufactured by Momentive Performance Materials GmbH); and BYK307, BYK323, and BYK330 (all manufactured by BYK-Chemie GmbH).

The photosensitive composition according to the present disclosure may include one kind of surfactant alone or may include two or more kinds of surfactants.

In a case where the photosensitive composition according to the present disclosure includes a surfactant, the content of the surfactant is preferably 0.001% by mass to 5% by mass, more preferably 0.01% by mass to 3% by mass, and particularly preferably 0.01% by mass to 1% by mass, with respect to the total mass of the photosensitive composition.

<<Solvent>>

The photosensitive composition according to the present disclosure may include a solvent. As the solvent, a known solvent can be utilized without limitation. Examples of the solvent include ethylene glycol monoalkyl ether-based solvents, ethylene glycol dialkyl ether-based solvents, ethylene glycol monoalkyl ether acetate-based solvents, propylene glycol monoalkyl ether-based solvents, propylene glycol dialkyl ether-based solvents, propylene glycol monoalkyl ether acetate-based solvents, diethylene glycol dialkyl ether-based solvents, diethylene glycol monoalkyl ether acetate-based solvents, dipropylene glycol monoalkyl ether-based solvents, dipropylene glycol dialkyl ether-based solvents, dipropylene glycol monoalkyl ether acetate-based solvents, ester-based solvents, ketone-based solvents (preferably, methyl ethyl ketone, methyl isobutyl ketone, cyclohexanone, and 2-heptanone), amide-based solvents (preferably dimethylformamide, dimethylacetamide, N-methylpyrrolidone, and N-ethylpyrrolidone), and lactone-based solvents.

It is preferable that the solvent includes at least one solvent selected from the group consisting of an ethylene glycol monoalkyl ether acetate-based solvent, a propylene glycol monoalkyl ether acetate-based solvent, a diethylene glycol monoalkyl ether acetate-based solvent, a dipropylene glycol monoalkyl ether acetate-based solvent, a propylene glycol monoalkyl ether-based solvent, and a ketone-based solvent, and it is particularly preferable that the solvent includes at least one solvent selected from the group consisting of propylene glycol monomethyl ether acetate, propylene glycol monomethyl ether, and methyl ethyl ketone.

The photosensitive composition according to the present disclosure may include one kind of solvent alone or may include two or more kinds of solvents.

The solid content concentration of the photosensitive composition according to the present disclosure is preferably 1% by mass to 50% by mass, more preferably 3% by mass to 40% by mass, and particularly preferably 5% by mass to 30% by mass.

<<Halogen>>

The photosensitive composition according to the present disclosure may include a halogen (including a halogen ion; hereinafter, the same applies).

The halogen content is preferably less than 100 ppm, more preferably 50 ppm or less, even more preferably 10 ppm or less, particularly preferably 5 ppm or less, and most preferably 1 ppm or less, with respect to the total mass of the photosensitive composition. As the halogen content is less than 100 ppm, an increase in the resistance value of a conductive layer can be suppressed. The lower limit of the halogen content is not limited and may be, for example, 0 ppm or more with respect to the total mass of the photosensitive composition. The halogen content may be 0 ppm or may be more than 0 ppm, with respect to the total mass of the photosensitive composition. The content of a halogen ion can be measured by ion chromatography. The content of an unionized halogen can be measured by combustion ion chromatography.

<<Viscosity>>

In a case where the photosensitive composition according to the present disclosure includes a solvent, from the viewpoint of coatability, the viscosity at 25° C. of the photosensitive composition is, for example, preferably 1 mPa·s to 50 mPa·s, more preferably 2 mPa·s to 40 mPa·s, and even more preferably 3 mPa·s to 30 mPa·s. Viscosity is measured using a viscometer. As the viscometer, for example, a viscometer manufactured by Toki Sangyo Co., Ltd. (trade name: VISCOMETER TV-22) can be suitably used.

<<Surface Tension>>

In a case where the photosensitive composition according to the present disclosure includes a solvent, for example, from the viewpoint of coatability, the surface tension at 25° C. of the photosensitive composition is preferably 5 mN/m to 100 mN/m, more preferably 10 mN/m to 80 mN/m, and even more preferably 15 mN/m to 40 mN/m. Surface tension is measured using a surface tensiometer. As the surface tensiometer, for example, a surface tensiometer manufactured by Kyowa Interface Science Co., Ltd. (trade name: Automatic Surface Tensiometer CBVP-Z) can be suitably used.

<<Method for Producing Photosensitive Composition>>

The method for producing the photosensitive composition according to the present disclosure is not limited. Regarding the method for producing a photosensitive composition according to the present disclosure, for example, a method of mixing a polymer having a polymerizable functional group in a side chain (that is, specific polymer) and an ammonium compound including an ammonium cation and a carboxylate anion (that is, specific ammonium compound) may be mentioned. Furthermore, a method of using a reaction mixture obtainable by the esterification step described in the above-described section “Method for producing specific polymer” may also be mentioned.

The method for producing a photosensitive composition according to the present disclosure is preferably a method using a reaction mixture obtainable by an esterification step. Specifically, it is preferable that the method for producing a photosensitive composition according to the present disclosure includes a step (esterification step) of forming a polymer having a polymerizable functional group in a side chain (that is, specific polymer) by reacting a polymer having a carboxy group with a polymerizable compound having a cyclic ether group in the presence of an ammonium compound (that is, specific ammonium compound) including an ammonium cation and a carboxylate anion. As the method for producing a photosensitive composition according to the present disclosure includes the above-described esterification step, a photosensitive composition capable of suppressing an increase in the resistance value of a conductive layer can be produced.

The esterification step in the method for producing a photosensitive composition according to the present disclosure is as described in the above-described section “Method for producing specific polymer”, and preferred aspects are also similar.

The reaction mixture obtainable by the esterification step usually includes a polymer having a polymerizable functional group in a side chain (that is, specific polymer), which is a product, and an ammonium compound including an ammonium cation and a carboxylate anion (that is, specific ammonium compound). For example, by diluting the reaction mixture obtainable by the esterification step with a solvent, a photosensitive composition adjusted to a target concentration can be obtained. The concentration of the specific ammonium compound in the photosensitive composition may be adjusted by adding the specific ammonium compound as necessary to the reaction mixture obtainable by the esterification step. Furthermore, by adding other components (for example, a polymerizable monomer and a photopolymerization initiator) as necessary to the reaction mixture obtainable by the esterification step, a photosensitive composition having a target composition can be obtained.

In the method for producing a photosensitive composition according to the present disclosure, the photosensitive composition may be produced by separating (for example, including isolation or purification) a polymer having a polymerizable functional group in a side chain obtainable by the esterification step (that is, specific polymer) and then adding the specific ammonium compound thereto. The purification method is not limited, and a known method such as a reprecipitation method in which a solution of the specific polymer is added to a poor solvent to precipitate and collect the specific polymer, can be utilized.

<<Use Application>>

Since the photosensitive composition according to the present disclosure can suppress an increase in the resistance value of a conductive layer, the photosensitive composition can be utilized, for example, to protect the conductive layer. It is preferable that the photosensitive composition according to the present disclosure is used as a protective film for a silver conductive material. The silver conductive material is a conductive material including silver.

<Transfer Film>

A transfer film according to the present disclosure has a temporary support and a layer including the photosensitive composition according to the present disclosure (hereinafter, may be referred to as “photosensitive layer”). By having a configuration such as described above, the transfer film according to the present disclosure can suppress an increase in the resistance value of a conductive layer.

<<Temporary Support>>

The transfer film according to the present disclosure has a temporary support. Examples of the temporary support include a glass substrate, a resin film, and paper. The temporary support is preferably a resin film from the viewpoints of strength and flexibility. Examples of the resin film include a cycloolefin polymer film, a polyethylene terephthalate film, a cellulose triacetate film, a polystyrene film, and a polycarbonate film. Among those described above, from the viewpoint of optical characteristics, the temporary support is preferably a polyethylene terephthalate film, and more preferably a biaxially stretched polyethylene terephthalate film. Furthermore, it is preferable that the film used as the temporary support does not have any deformation such as creases, scratches, and the like.

The resin film can be purchased as, for example, CERAPEEL (registered trademark) 25WZ manufactured by Toray Advanced Film Co., Ltd., and LUMIRROR (registered trademark) 16QS62 manufactured by Toray Industries, Inc.

The temporary support is preferably transparent. As the temporary support is transparent, the photosensitive layer can be exposed, for example, through the temporary support. In the present disclosure, the term “transparent” means that the total light transmittance at a wavelength of 380 nm to 780 nm measured at a temperature of 23° C. is 85% or higher (preferably 90% or higher, and more preferably 95% or higher). The total light transmittance is measured using a spectrophotometer (for example, spectrophotometer “U-3310 (trade name)” manufactured by Hitachi, Ltd.).

From the viewpoints of ease of handling and versatility, the average thickness of the temporary support is preferably 5 μm to 200 μm, preferably 10 μm to 150 μm, and particularly preferably 10 μm to 50 μm. The average thickness of the temporary support is defined as the arithmetic mean of the thicknesses at five sites measured by cross-sectional observation using a scanning electron microscope (SEM).

From the viewpoints of the pattern formability during pattern exposure via the temporary support and the transparency of the temporary support, it is preferable that the haze of the temporary support is smaller. Specifically, the haze value of the temporary support is preferably 2% or less, more preferably 0.5% or less, and particularly preferably 0.1% or less.

From the viewpoints of the pattern formability during pattern exposure via the temporary support and the transparency of the temporary support, it is preferable that the number of particles, foreign substances, and defects included in the temporary support is smaller.

The number of particles, foreign substances, and defects having a diameter of 1 μm or more on the surface of the temporary support is preferably 50 pieces/10 mm² or less, more preferably 10 pieces/10 mm² or less, and even more preferably 3 pieces/10 mm² or less.

From the viewpoint of imparting handleability, it is preferable that the temporary support has a filler on the surface on the opposite side of the photosensitive layer. Examples of the filler include silicon oxide particles and aluminum oxide particles.

Preferred aspects of the temporary support are described in, for example, paragraph 0017 to paragraph 0018 of JP2014-85643A, paragraph 0019 to paragraph 0026 of JP2016-27363A, and paragraph 0041 to paragraph 0057 of WO2012/081680A, and paragraph 0029 to paragraph 0040 of WO2018/179370A, the contents of which are all incorporated herein.

A particularly preferred temporary support may be a biaxially stretched polyethylene terephthalate film having an average thickness of 16 μm, a biaxially stretched polyethylene terephthalate film having an average thickness of 12 μm, or a biaxially stretched polyethylene terephthalate film having an average thickness of 10 μm.

<<Layer including Photosensitive Composition (Photosensitive Layer)>>

A transfer film according to the present disclosure has a layer including the photosensitive composition according to the present disclosure.

The photosensitive composition is as described in the above-described section “Photosensitive composition”, and preferred aspects are also similar.

The content of the solid content of the layer including the photosensitive composition is preferably 90% by mass to 99.99% by mass, more preferably 95% by mass to 99.9% by mass, and particularly preferably 97% by mass to 99.9% by mass, with respect to the total mass of the layer including the photosensitive composition.

From the viewpoint of storage stability, lamination properties, and durability of the transfer film, the moisture content of the layer including the photosensitive composition is preferably 0.001% by mass to 3% by mass, more preferably 0.005% by mass to 2% by mass, and particularly preferably 0.01% by mass to 1% by mass, with respect to the total mass of the layer including the photosensitive composition. A specific value may be 0.2% by mass.

From the viewpoint of lamination properties and resolution, the average thickness of the photosensitive layer is preferably 0.1 μm to 30 μm, more preferably 1 μm to 15 μm, and particularly preferably 1 μm to 10 μm. The average thickness of the photosensitive layer is defined as the arithmetic mean of the thicknesses at five sites measured by cross-sectional observation using a scanning electron microscope (SEM).

In the transfer film according to the present disclosure, it is preferable that a predetermined content of impurities are included in the photosensitive layer from the viewpoint of enhancing reliability and patterning properties. Specific examples of the impurities include sodium, potassium, magnesium, calcium, iron, manganese, copper, aluminum, titanium, chromium, cobalt, nickel, zinc, tin, and ions thereof. Among those described above, sodium ions and potassium ions are likely to be mixed in as impurities, and therefore, it is particularly preferable to adjust the content to the following content.

The content of impurities in the photosensitive layer is preferably 100 ppm or less, more preferably 20 ppm or less, and particularly preferably 5 ppm or less, on a mass basis. The content of impurities in the photosensitive layer may be, for example, 1 ppb or more or may be 10 ppb or more, on a mass basis, as long as the content is not more than the above-described upper limit value.

As a method for reducing the content of impurities in the photosensitive layer to 100 ppm or less on a mass basis, for example, a method of selecting raw materials of the photosensitive layer having a low content of impurities, a method of preventing incorporation of impurities at the time of forming the photosensitive layer, and a method of cleaning the photosensitive layer to remove impurities, may be mentioned.

Impurities included in the photosensitive layer can be quantified by a known method such as, for example, Inductively Coupled Plasma (ICP) emission spectroscopy, atomic absorption spectroscopy, or ion chromatography.

It is preferable that the photosensitive layer has a low content of compounds such as benzene, formaldehyde, trichlorethylene, 1,3-butadiene, carbon tetrachloride, chloroform, N,N-dimethylformamide, N,N-dimethylacetamide, and hexane (hereinafter, referred to as “compounds X”). The content of the compounds X in the photosensitive layer is preferably 1,000 ppm or less, more preferably 200 ppm or less, and particularly preferably 40 ppm or less, on a mass basis. The content of the compounds X in the photosensitive layer may be, for example, 10 ppb or more or may be 100 ppb or more, on a mass basis, as long as the content is not more than the above-described upper limit value. Regarding the method for reducing the content of the compounds X in the photosensitive layer to 1,000 ppm or less on a mass basis, method similar to the methods in the case of impurities may be mentioned. Furthermore, the compounds X included in the photosensitive layer can be quantified by a known method.

<<Color of Photosensitive Layer>>

It is preferable that the photosensitive layer is achromatic. Specifically, the total reflection (incident angle: 8°, light source: D-65, and visual field: 2°) of the photosensitive layer is such that in the CIE 1976 (L*, a*, b*) color space, the L* value is preferably 10 to 90, the a* value is preferably −1.0 to 1.0, and the b* value is preferably −1.0 to 1.0.

Regarding the method for forming the photosensitive layer, a method of applying a photosensitive composition on an object to be coated (for example, a temporary support) may be mentioned. Examples of the coating method include a printing method, a spraying method, a roll coating method, a bar coating method, a curtain coating method, a spin coating method, and a die coating method (that is, a slit coating method). Among those described above, the coating method is preferably a die coating method.

In the method for forming the photosensitive layer, the photosensitive composition applied on the object to be coated (for example, a temporary support) may be dried as necessary. Examples of the drying method include natural drying, drying by heating, and drying under reduced pressure.

<<Antistatic Layer>>

The transfer film according to the present disclosure may have an antistatic layer. As the transfer film according to the present disclosure has an antistatic layer, the generation of static electricity in a case of peeling off a film or the like disposed on the antistatic layer can be suppressed, and the generation of static electricity caused by rubbing against facilities or other films can also be suppressed. As a result, for example, the occurrence of inconvenience in electronic devices can be suppressed.

From the viewpoint of suppressing the generation of static electricity, it is preferable that the antistatic layer is disposed between the temporary support and the photosensitive layer.

The antistatic layer is a layer having antistatic properties and includes at least an antistatic agent. As the antistatic agent, a known antistatic agent can be used without limitation.

It is preferable that the antistatic layer includes, as an antistatic agent, at least one compound selected from the group consisting of an ionic liquid, an ionic conductive polymer, an ionic conductive filler, and an electrically conductive polymer.

The ionic liquid is preferably an ionic liquid composed of a fluoroorganic anion and an onium cation.

Examples of the ionic conductive polymer include an ionic conductive polymer obtained by polymerizing or copolymerizing a monomer having a quaternary ammonium base. As the counter ion of the quaternary ammonium base, a non-halogen ion is preferred. Examples of non-halogen ion include a sulfonate anion and a carboxylate anion.

Examples of the ion conductive filler include tin oxide, antimony oxide, indium oxide, cadmium oxide, titanium oxide, zinc oxide, indium, tin, antimony, gold, silver, copper, aluminum, nickel, chromium, titanium, iron, cobalt, copper iodide, indium oxide/tin oxide (ITO), and antimony oxide/tin oxide (ATO).

Examples of the electrically conductive polymer include polythiophene, polyaniline, polypyrrole, polyethyleneimine, and an allylamine-based polymer. Specific examples of the electrically conductive polymer include (3,4-ethylenedioxythiophene)-poly(styrenesulfonic acid).

Among those described above, the antistatic agent is preferably polythiophene. Regarding the polythiophene, a polymer compound including poly(3,4-ethylenedioxythiophene) (PEDOT) is preferred, and an electrically conductive polymer consisting of poly (3,4-ethylenedioxythiophene) and polystyrene sulfonic acid (hereinafter, abbreviated as “PEDOT/PSS”) is particularly preferred.

The antistatic layer may include one kind of antistatic agent alone or may include two or more kinds of antistatic agents.

From the viewpoint of antistatic properties, the content of the antistatic agent is preferably 0.1% by mass to 100% by mass with respect to the total mass of the layer including the antistatic layer. In a case where the antistatic agent is a solvent-dispersed antistatic agent, the content of the antistatic agent is more preferably 1% by mass to 10% by mass, and particularly preferably 3% by mass to 10% by mass, with respect to the total mass of the antistatic layer. In a case where the antistatic agent is not a solvent-dispersed antistatic agent, the content of the antistatic agent is more preferably 60% by mass to 100% by mass, and particularly preferably 70% by mass to 100% by mass, with respect to the total mass of the antistatic layer.

The antistatic layer may further contain components other than the antistatic agent as necessary. Examples of components other than the antistatic agent include a binder polymer (for example, polyvinylpyrrolidone, polyvinyl alcohol, and an acrylic resin), a curable component (for example, a polymerizable compound and a photopolymerization initiator), and a surfactant.

It is preferable that a predetermined content of impurities are included in the antistatic layer. Specific examples of the impurities include the impurities such as sodium described in the above-described section “Photosensitive layer”. Aspects of the content of impurities in the antistatic layer are similar to the aspects of the content of impurities in the photosensitive layer as described in the above-described section “Photosensitive layer”. Furthermore, the method for adjusting the content of impurities and the method for measuring impurities are as described in the above-described section “Photosensitive layer”.

It is preferable that the antistatic layer has a low content of compounds such as benzene, formaldehyde, trichlorethylene, 1,3-butadiene, carbon tetrachloride, chloroform, N,N-dimethylformamide, N,N-dimethylacetamide, and hexane (hereinafter, referred to as “compounds Y”). A preferred range of the content of the compounds Y in the antistatic layer is similar to the preferred range of the content of the compounds X in the photosensitive layer as described in the above-described section “Photosensitive layer”. Furthermore, the method for adjusting the content of the compound Y and the method for measuring the compound Y are the same as the method for the compound X in the photosensitive layer described in the above-described section “Photosensitive layer”.

The average thickness of the antistatic layer is preferably 1 μm or less, more preferably 0.6 μm or less, even more preferably 0.4 μm or less, and particularly preferably 0.2 μm or less. As the average thickness of the antistatic layer is 1 μm or less, the haze can be lowered. The lower limit of the thickness of the antistatic layer is not limited. From the viewpoint of production suitability, the average thickness of the antistatic layer is preferably 0.01 μm or more. The average thickness of the antistatic layer is defined as the arithmetic mean of the thicknesses at five sites measured by cross-sectional observation using a scanning electron microscope (SEM).

Examples of the method for forming the antistatic layer include a method of using a composition for an antistatic layer. For example, a method of applying a composition for an antistatic layer on an object to be coated (for example, a temporary support or a photosensitive layer) may be mentioned. Examples of the coating method include a printing method, a spraying method, a roll coating method, a bar coating method, a curtain coating method, a spin coating method, and a die coating method (that is, a slit coating method). Among those described above, the coating method is preferably a die coating method.

In the method for forming the antistatic layer, the photosensitive composition applied on the object to be coated may be dried as necessary. Examples of the drying method include natural drying, drying by heating, and drying under reduced pressure.

<<Protective Layer>>

The transfer film according to the present disclosure may have a protective layer on a surface of the photosensitive layer, the surface being on the opposite side of the side where the temporary support is disposed. Furthermore, in a case where an antistatic layer is disposed between the temporary support and the photosensitive layer, the transfer film according to the present disclosure may have a protective layer on a surface of the photosensitive layer, the surface being on the opposite side of the side where the antistatic layer is disposed.

Examples of the protective layer include a glass substrate, a resin film, and paper. The protective layer is preferably a resin film from the viewpoint of strength and flexibility. Examples of the resin film include a cycloolefin polymer film, a polypropylene film, a polyethylene terephthalate film, a cellulose triacetate film, a polystyrene film, and a polycarbonate film. Among those described above, from the viewpoint of handleability, the protective layer is preferably a polypropylene film or a polyethylene terephthalate film.

Examples of the resin film include CERAPEEL (registered trademark) 25WZ manufactured by Toray Advanced Film Co., Ltd., ALPHAN (registered trademark) FG-201 manufactured by Oji F-Tex Co., Ltd., ALPHAN (registered trademark) E-201F manufactured by Oji F-Tex Co., Ltd., and LUMIRROR (registered trademark) 16QS62 manufactured by Toray Industries, Inc.

The protective layer may be transparent. The protective layer may have a release layer in order to facilitate peeling of the protective layer.

From the viewpoints of ease of handling and versatility, the average thickness of the protective layer is preferably 5 μm to 200 μm, more preferably 10 μm to 150 μm, and particularly preferably 10 μm to 50 μm. The average thickness of the protective layer is defined as the arithmetic mean of the thicknesses at five sites measured by cross-sectional observation using a scanning electron microscope (SEM).

<Cured Film>

The cured film according to the present disclosure is a cured film of the photosensitive composition according to the present disclosure. As the cured film according to the present disclosure is a cured film of the photosensitive composition of the present disclosure, an increase in the resistance value of the conductive layer can be suppressed.

The cured film of the photosensitive composition according to the present disclosure is a film obtained by curing the photosensitive composition according to the present disclosure. The cured film includes the components constituting the photosensitive composition according to the present disclosure. The photosensitive composition is as described in the above-described section “Photosensitive composition”, and preferred aspects are also similar. The curable components included in the photosensitive composition (for example, a polymer having a polymerizable functional group in a side chain, and a polymerizable monomer) may be present as a polymerized cured product in the cured film.

The cured film according to the present disclosure may include components that cure the photosensitive composition (for example, a polymer having a polymerizable functional group in a side chain, a polymerizable monomer, and a photopolymerization initiator), and a solvent, as long as the effect of the cured film is not impaired.

The cured film according to the present disclosure can be produced by curing the photosensitive composition according to the present disclosure. For example, a cured film can be formed by applying the photosensitive composition on a member to be coated (for example, a substrate or a conductive layer) and then curing the photosensitive composition.

Examples of the coating method include a printing method, a spraying method, a roll coating method, a bar coating method, a curtain coating method, a spin coating method, and a die coating method (that is, a slit coating method).

Regarding the method of curing the photosensitive composition, a known method can be used without limitation. As the method of curing the photosensitive composition, for example, a method of curing the photosensitive composition by exposure may be mentioned. Furthermore, as the method of curing the photosensitive composition, for example, a method of curing the photosensitive composition by means of heat may be mentioned.

Examples of the light source include various lasers, a light emitting diode (LED), an ultrahigh-pressure mercury lamp, a high-pressure mercury lamp, and a metal halide lamp.

The exposure wavelength is not limited as long as it is a wavelength capable of curing the photosensitive composition. Examples of the exposure wavelength include wavelength ranges including 254 nm, 365 nm, or 405 nm.

The exposure amount is preferably 5 mJ/cm² to 400 mJ/cm², and more preferably 10 mJ/cm² to 400 mJ/cm².

In a case where the photosensitive composition includes a solvent, it is preferable to dry the photosensitive composition before exposing the photosensitive composition. Examples of the drying method include natural drying, drying by heating, and drying under reduced pressure.

The cured film according to the present disclosure may also be produced by using the transfer film according to the present disclosure. For example, a cured film can be produced by sticking the transfer film according to the present disclosure and a transfer-receiving member (for example, a substrate or a conductive layer) together and then exposing the photosensitive layer in the transfer film. The exposure conditions are as described above. At the time of exposing the photosensitive layer, the photosensitive layer may be exposed through the temporary support. Furthermore, it is also acceptable that the photosensitive layer is exposed after the temporary support is removed from the photosensitive layer.

As the method of sticking the transfer film and the transfer-receiving member together (hereinafter, may be referred to as “lamination”), for example, a method of sticking the transfer film and the transfer-receiving member together such that the photosensitive layer in the transfer film and the transfer-receiving member come into contact with each other may be mentioned.

In a case where the transfer film has a protective layer, the transfer film and the transfer-receiving member are stuck together after the protective layer is removed from the transfer film. Specifically, the photosensitive layer is exposed by removing the protective layer from the transfer film, and then the transfer film and the transfer-receiving member are stuck together such that the exposed photosensitive layer and the transfer-receiving member come into contact with each other.

Lamination can be carried out using a known laminator. Examples of the laminator include a vacuum laminator and an auto-cut laminator.

The lamination temperature is preferably 80° C. to 150° C., more preferably 90° C. to 150° C., and particularly preferably 100° C. to 150° C. For example, when a laminator equipped with a pressing member (for example, a rubber roller) is used, the lamination temperature indicates the temperature of the pressing member.

The pressure during lamination (so-called linear pressure) is preferably 0.01 MPa to 100 MPa, more preferably 0.1 MPa to 10 MPa, and particularly preferably 0.1 MPa to 5 MPa.

The transportation speed during lamination (so-called lamination speed) is preferably 0.5 m/min to 5 m/min, and more preferably 1.5 m/min to 3 m/min.

In the production of the cured film according to the present disclosure, the exposed photosensitive composition may be subjected to a heating treatment (referred to as “post-baking”). By performing the heating treatment, curability of the cured film can be enhanced. The heating temperature is preferably 100° C. to 160° C., and more preferably 130° C. to 160° C. The heating time is preferably 10 to 60 minutes.

<<Color of Cured Film>>

The cured film is preferably achromatic. Specifically, the total reflection (incident angle: 8°, light source: D-65, and visual field: 2°) of the photosensitive layer is such that in the CIE 1976 (L*, a*, b*) color space, the L* value is preferably 10 to 90, the a* value is preferably −1.0 to 1.0, and the b* value is preferably −1.0 to 1.0.

<Laminate>

A laminate according to the embodiment of the present disclosure has a substrate, a conductive layer, and a cured film of the photosensitive composition according to the present disclosure (hereinafter, may be simply referred to as “cured film”). By having a configuration such as described above, the laminate according to the present disclosure can suppress an increase in the resistance value of a conductive layer.

<<Substrate>>

The laminate according to the present disclosure has a substrate. Regarding the substrate, a known substrate can be used without limitation. The substrate is preferably a glass substrate or a resin substrate. The substrate is preferably a transparent substrate, and more preferably a transparent resin substrate.

Examples of the glass substrate include tempered glass. Tempered glass is available, for example, as Gorilla Glass (registered trademark) by Corning, Inc.

Examples of the resin substrate include polyethylene terephthalate (PET), polyethylene naphthalate (PEN), polycarbonate (PC), triacetyl cellulose (TAC), polyimide (PI), polybenzoxazole (PBO), and a cycloolefin polymer (COP). As the resin substrate, it is preferable to use at least one of an optically undistorted resin substrate or a resin substrate having high transparency.

Regarding the material of the transparent substrate, for example, the materials described in JP2010-86684A, JP2010-152809A, and JP2010-257492A are preferable.

The refractive index of the substrate is preferably 1.50 to 1.52.

The thickness of the substrate is not limited and may be determined in the range of, for example, 10 μm to 1 mm.

<<Conductive Layer>>

The laminate according to the present disclosure has a conductive layer. With regard to the laminate according to the present disclosure, it is preferable that the conductive layer is disposed between the substrate and the cured film of the photosensitive composition, or on a surface of the cured film of the photosensitive composition, the surface being on the opposite side of the side where the substrate is disposed.

The conductive layer is a conductive layer including a metal. The form of the metal is not limited and may be, for example, in a particulate form or a wire form. Examples of the metal include silver, copper, and alloys thereof. The metal is preferably silver, and more preferably a silver nanowire. According to the present disclosure, a conductive layer including a silver nanowire is referred to as “layer including a silver nanowire”. Hereinafter, a silver nanowire will be specifically described.

[Silver Nanowire]

Examples of the shape of the silver nanowire include a cylindrical shape, a rectangular parallelepiped shape, and a columnar shape having a polygonal cross-section. In use applications where high transparency is required, it is preferable that the silver nanowire has at least one shape of a cylindrical shape or a columnar shape having a polygonal cross-section. The cross-sectional shape of the silver nanowire can be observed using, for example, a transmission electron microscope (TEM).

The diameter (so-called minor axis length) of the silver nanowire is not limited. From the viewpoint of transparency, the diameter of the silver nanowire is preferably 50 nm or less, more preferably 35 nm or less, and particularly preferably 20 nm or less. From the viewpoints of oxidation resistance and durability, the diameter of the silver nanowire is preferably 5 nm or more.

The length (so-called major axis length) of the silver nanowire is not limited. From the viewpoint of conductivity, the length of the silver nanowire is preferably 5 μm or more, more preferably 10 μm or more, and particularly preferably 30 μm or more. From the viewpoint of suppressing the generation of aggregates during the production process, the length of the silver nanowires is preferably 1 mm or less.

The diameter and the length of the silver nanowires can be measured, for example, using a transmission electron microscope (TEM) or an optical microscope. Specifically, the diameters and the lengths of 300 pieces of silver nanowires randomly selected from the silver nanowires magnified and observed using a transmission electron microscope (TEM) or an optical microscope are measured. The value obtained by arithmetically averaging the diameters of 300 pieces of the silver nanowires is defined as the diameter of the silver nanowires. The value obtained by arithmetically averaging the lengths of 300 pieces of the silver nanowires is defined as the length of the silver nanowires.

The content of the silver nanowire in the conductive layer is not limited. From the viewpoints of transparency and conductivity, the content of the silver nanowire is preferably 1% by mass to 99% by mass, and more preferably 10% by mass to 95% by mass, with respect to the total mass of the conductive layer.

Regarding the method for producing the silver nanowire, a known method can be utilized without limitation. As a method for producing a silver nanowire, for example, a method of adding a silver complex solution to an aqueous solvent including at least a halogen compound and a reducing agent, subsequently heating the mixture at a temperature of 150° C. or lower, and then performing a desalting treatment as necessary, may be mentioned.

As the method for producing a silver nanowire, the methods described in paragraph 0020 to paragraph 0031 of JP2013-167021A can also be utilized. These descriptions are incorporated herein by reference.

[Binder]

The conductive layer may include a binder (also referred to as “matrix”) as necessary. The binder is a solid material in which metal (for example, silver nanowires) is dispersed or embedded, in the conductive layer.

Examples of the binder include a polymer material and an inorganic material. It is preferable that the binder is a material having light transmitting properties.

Examples of the polymer material include a (meth)acrylic resin (for example, poly(methyl methacrylate)), a polyester (for example, polyethylene terephthalate (PET)), a polycarbonate, a polyimide, a polyamide, a polyolefin (for example, polypropylene), a polynorbornene, a cellulose compound, polyvinyl alcohol (PVA), and polyvinylpyrrolidone.

Examples of the cellulose compound include hydroxypropylmethyl cellulose (HPMC), hydroxyethyl cellulose (HEC), methylcellulose (MC), hydroxypropyl cellulose (HPC), and carboxymethyl cellulose (CMC).

The polymer material may be a conductive polymer material. Examples of the conductive polymer material include polyaniline and polythiophene.

Examples of the inorganic material include silica, mullite, and alumina.

As the binder, those described in paragraphs 0051 and 0052 of JP2014-212117A can also be used.

The conductive layer may include one kind of binder alone or may include two or more kinds of binders.

In a case where the conductive layer includes a binder, the content of the binder is preferably 1% by mass to 99% by mass, and more preferably 5% by mass to 80% by mass, with respect to the total mass of the conductive layer.

[Thickness]

The thickness of the conductive layer is not limited. From the viewpoints of transparency and conductivity, the average thickness of the conductive layer is preferably 1 nm to 400 nm, and more preferably 10 nm to 200 nm. As the thickness of the conductive layer is in the above-described range, an electrode having low resistance can be relatively easily formed.

The average thickness of the conductive layer is measured by the following method. In a cross-sectional observation image in the thickness direction of the conductive layer, the thickness of the conductive layer is measured at any five sites. The measured values are arithmetically averaged, and the obtained value is taken as the average thickness of the conductive layer. A cross-sectional observation image of the conductive layer in the thickness direction can be obtained by using a scanning electron microscope (SEM).

[Method for Forming Conductive Layer]

Regarding the method for forming a conductive layer, a known method can be used without limitation. For example, the conductive layer can be formed by applying a composition for a conductive layer on a substrate.

The composition for a conductive layer can be prepared by mixing each of the above components and optionally a solvent. Regarding the solvent, a known solvent can be used without limitation.

Examples of the coating method include a printing method, a spraying method, a roll coating method, a bar coating method, a curtain coating method, a spin coating method, and a die coating method (that is, a slit coating method).

In the method for forming a conductive layer, the composition for a conductive layer applied on the substrate may be dried as necessary. Examples of the drying method include natural drying, drying by heating, and drying under reduced pressure.

<<Cured Film>>

The laminate according to the present disclosure has a cured film of the photosensitive composition according to the present disclosure. With regard to the laminate according to the present disclosure, it is preferable that the cured film is in contact with the conductive layer. Since the cured film is in contact with the conductive layer, an increase in the resistance value of the conductive layer can be suppressed.

The cured film is as described in the above-described section “Cured film” (that is, the cured film of the present disclosure), and preferred aspects are also similar.

Regarding the method for forming a cured film, for example, the methods described in the above-described section “Cured film” (that is, the cured film of the present disclosure) may be mentioned. For example, a cured film can be formed by applying the photosensitive composition according to the present disclosure on a substrate or a conductive layer (including a conductive layer disposed on a substrate; hereinafter, the same in this paragraph), and then curing the photosensitive composition. Furthermore, a cured film can also be formed by sticking the transfer film according to the present disclosure onto a substrate or a conductive layer and then curing the photosensitive layer in the transfer film.

<<Other Layers>>

The laminate according to the present disclosure may have a substrate, a conductive layer, and a layer other than a cured film (hereinafter, may be referred to as “other layer”) as necessary.

Examples of the other layer include an adhesive layer and a refractive index adjusting layer. As the other layer, the antistatic layer described in the above-described section “Antistatic layer” may also be mentioned.

<<Use Application>>

Since the laminate according to the present disclosure can suppress an increase in the resistance value of a conductive layer, the laminate can be utilized for a touch panel, for example.

<Touch Panel>

A touch panel according to the present disclosure has the laminate according to the present disclosure. As the touch panel according to the present disclosure has the above-described laminate, an increase in the resistance value of the conductive layer can be suppressed.

The laminate is as described in the above-described section “Laminate”, and preferred aspects are also similar.

With regard to the touch panel according to the present disclosure, the conductive layer may form a lead wire (so-called extraction wiring) disposed at the frame part of the touch panel or may form an electrode disposed at the visual recognition part of the touch panel. It is preferable that the conductive layer forms an electrode disposed at the viewing part of the touch panel.

Examples of the method for detecting a touch panel according to the present disclosure include a resistance film method, a capacitance method, an ultrasonic method, an electromagnetic induction method, and an optical method. Among those described above, the detection method is preferably a capacitance method.

Regarding the touch panel type, for example, a so-called in-cell type (for example, as shown in FIG. 5, FIG. 6, FIG. 7, and FIG. 8 of JP2012-517051A), and a so-called on-cell type (for example, as shown in FIG. 19 of JP2013-168125A, and as shown in FIG. 1 and FIG. 5 of JP2012-89102A), One Glass Solution (OGS) type, Touch-on-Lens (TOL) type (for example, as shown in FIG. 2 of JP2013-54727A), other configurations (for example, as shown in FIG. 6 of JP2013-164871A), and various out-cell types (so-called GG, G1, G2, GFF, GF2, GF1, and G1F).

Regarding a method for producing the touch panel according to the present disclosure, a known method can be utilized without limitation. In the method for producing the touch panel according to the present disclosure, for example, the method for producing a laminate according to the present disclosure can be applied. For example, the touch panel according to the present disclosure can be produced by sticking the transfer film according to the present disclosure to a substrate for a touch panel having a conductive layer on at least one surface thereof, and then performing pattern exposure and developing.

### EXAMPLES

Hereinafter, the present disclosure will be described in detail by way of Examples; however, the present disclosure is not intended to be limited to these. That is, the materials, amounts of use, proportions, treatment contents, treatment procedures, and the like shown in the following Examples can be appropriately modified without departing from the purport of the present disclosure. In the following Examples, unless particularly stated otherwise, the weight-average molecular weight is the weight-average molecular weight determined by gel permeation chromatography (GPC) and calculated relative to polystyrene standards. The acid value was measured according to the method described in JIS K 0070:1992.

[Synthesis of Polystyrene Sulfonate]

206 g of sodium styrene sulfonate was dissolved in 1000 mL of ion exchange water, subsequently 1.14 g of an aqueous solution of an ammonium persulfate oxidizing agent dissolved in advance in 10 mL of water was added dropwise thereto for 20 minutes while being stirred at 80° C., and then the solution was stirred for 12 hours. 1000 mL of sulfuric acid diluted to 10% by mass was added to the obtained aqueous solution containing sodium polystyrene sulfonate, and then 1000 mL of the solution of the aqueous solution containing polystyrene sulfonate was removed by using an ultrafiltration method. 2000 mL of ion-exchanged water was added to the residual liquid, and then about 2000 mL of the solution was removed by using an ultrafiltration method. The above-described ultrafiltration operation was repeated three times. Furthermore, about 2000 mL of ion-exchanged water was added to the obtained filtrate, and then about 2000 mL of the solution was removed by using an ultrafiltration method. This ultrafiltration operation was repeated three times. The water in the obtained solution was removed under reduced pressure to obtain a colorless solid substance. The weight-average molecular weight of the obtained polystyrene sulfonate was measured by using a high performance liquid chromatography (HPLC) system that used a gel permeation chromatography (GPC) column and using Pullulan manufactured by Showa Denko K.K. as a standard substance, and as a result, the molecular weight was 300,000.

[Preparation of Anti static Agent AS-1]

14.2 g of 3,4-ethylenedioxythiophene and a solution obtained by dissolving the above-described polystyrene sulfonate (36.7 g) in 2000 mL of ion-exchanged water were mixed at 20° C., and a mixed solution was obtained. While maintaining the obtained mixed solution at 20° C. and performing stirring, a solution obtained by dissolving 29.64 g of ammonium persulfate in 200 mL of ion-exchanged water and an oxidation catalyst solution of 8.0 g of ferric sulfate were slowly added thereto, the mixture was caused to react by stirring for 3 hours, and a reaction liquid was obtained. 2000 mL of ion-exchanged water was added to the obtained reaction liquid, and then about 2000 mL of the solution was removed by using an ultrafiltration method. This operation was repeated three times. Next, 200 mL of a 10% by mass aqueous solution of sulfuric acid and 2000 mL of ion-exchanged water were added to the obtained solution, and about 2000 mL of the solution was removed by using an ultrafiltration method. 2000 mL of ion-exchanged water was added to the residual liquid, and then about 2000 mL of the solution was removed by using an ultrafiltration method. This operation was repeated three times. Furthermore, 2000 mL of ion-exchanged water was added to the obtained solution, and then about 2000 mL of the solution was removed by using an ultrafiltration method. This operation was repeated five times, and a blue 1.2% by mass aqueous solution of PEDOT/PSS was obtained. The aqueous solution (100 g) of PEDOT/PSS obtained as described above and 100 g of methanol were mixed, and a mixed liquid of 200 g of methanol and 12.5 g of C12 and C13 mixed higher alcohol glycidyl ether was added dropwise for 60 minutes while being stirred at 50° C. to obtain a dark blue precipitate. This precipitate was collected by filtration and then was dispersed in methyl ethyl ketone (MEK) to obtain a 1% by mass MEK dispersion liquid of PEDOT/PSS (AS-1).

[Preparation of Composition for Antistatic Layer]

A composition for an antistatic layer (B-1) having the composition shown in the following Table 1 was prepared. In the following Table 1, the unit of the numerical value described in the column for each component is parts by mass.

TABLE 1

| Composition for antistatic layer | | B-1 |
|---|---|---|
| Radically | 1,10-Decanediol diacrylate | 1.04 |
| polymerizable | (A-DOD-N, manufactured by Shin-Nakamura Chemical Co., Ltd.) | |
| compound | 75% by mass PGMEA solution of | 1.36 |
| | dipentaerythritol hexaacrylate | |
| | (KAYARD DPHA, manufactured by Nippon Kayaku Co., Ltd.) | |
| Polymer | 27% by mass PGMEA solution of P-1 (Acid value 113 mgKOH/g) | 9.59 |
| Photo- | 1-[9-Ethyl-6-(2-methylbenzoyl)-9H-carbazol-3-yl]ethanone-, 1-(O- | 0.02 |
| polymerization | acetyloxime) (IRGACURE OXE-02, manufactured by BASF SE) | |
| initiator | 2-Methyl-1-(4-methylthiophenyl)-2-morpholinopropan-1-one | 0.05 |
| | (IRGACURE 907, manufactured by BASF SE) | |
| Antistatic | Electrically conductive polymer | 25.00 |
| agent | AS-1 (1% by mass MEK dispersion liquid of PEDOT/PSS) | |
| Surfactant | MEGAFACE F551A (manufactured by DIC Corporation) | 0.05 |
| | (30% by mass PGMEA solution) | |
| Solvent | Propylene glycol monomethyl ether acetate | 59.13 |
| | (PGMEA) | |
| | Methyl ethyl ketone | 3.75 |
| | (MEK) | |

Polymer P-1 shown in the above-described Table 1 is a polymer having the following structure. The composition ratio shown in the following structure is a molar ratio. Polymer P-1 is an alkali-soluble acrylic resin having a weight-average molecular weight of 30,000.

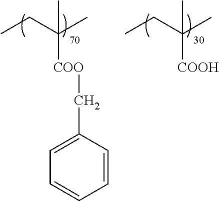

[Synthesis of Polymer (I-1)]

Under a nitrogen gas stream, a solution obtained by mixing styrene (38.4 g), methacrylic acid (34.0 g), dicyclopentanyl methacrylate (30.1 g), V-601 (trade name; manufactured by FUJIFILM Wako Pure Chemical Corporation, 5.4 g) as a polymerization initiator, and propylene glycol monomethyl ether (63.6 g), was added dropwise for 3 hours to propylene glycol monomethyl ether (82.4 g) heated to 90° C. Next, the mixture was caused to react for 1 hour at 90° C., and then 0.75 g each of V-601 was added thereto three times at an interval of 1 hour. Next, the mixture was caused to react for another 3 hours at 90° C. to obtain a reaction solution, and then the obtained reaction solution was diluted with propylene glycol monomethyl ether acetate (58.4 g) and propylene glycol monomethyl ether (11.7 g) to obtain a polymer solution. To the obtained polymer solution, glycidyl methacrylate (trade name: BLEMMER GH, manufactured by NOF Corporation, 25.5 g), which is a polymerizable compound having a cyclic ether group, and tetrabutylammonium acetate (manufactured by Tokyo Chemical Industry Co., Ltd., 1.14 g), which is an ammonium carboxylic acid salt, as a catalyst, and p-methoxyphenol (0.26 g) were added and mixed, and the mixture was caused to react at 100° C. for 7 hours under an air stream to obtain a solution including Polymer (I-1). Propylene glycol monomethyl ether acetate was added to the obtained solution including Polymer (I-1) to obtain a polymer solution having a solid content concentration of 27% by mass. The residual amount of glycidyl methacrylate in this polymer solution was measured by gas chromatography (GC), and the residual amount was 0.1% by mass or less. The weight-average molecular weight of the obtained polymer was 17,000, and the dispersity was 2.1. The dispersity was measured by GPC in the same manner as in the case of the weight-average molecular weight. The acid value of the polymer determined by the following Formula X was 94.5 mgKOH/g.

Formula X: Acid value of polymer=(acid value of solution)/(solid content concentration)

[Synthesis of Polymer (I-2) to Polymer (I-7) and Polymer (IX-1) to Polymer (IX-5)]

Solutions respectively including Polymer (I-2) to Polymer (I-7) and Polymer (IX-1) to Polymer (IX-5) were obtained by procedures similar to that for the Polymer (I-1), except that the type and the amount of addition of the catalyst were changed according to the description in the following Table 2. The solid content concentration of each of the polymer solutions is 27% by mass.

TABLE 2

| | | Amount of |
|---|---|---|
| | | addition |
| Polymer | Catalyst | (g) |
| I-1 | Tetrabutylammonium acetate | 1.14 |
| I-2 | Tetramethylammonium acetate | 1.14 |
| I-3 | Anhydrous betaine | 1.14 |
| I-4 | Tetrabutylammonium salicylate | 1.14 |
| I-5 | Tetrabutylammonium acetate | 0.57 |
| I-6 | Tetrabutylammonium acetate | 4.9 |
| I-7 | Tetrabutylammonium acetate | 11.4 |
| IX-1 | Tetraethylammonium bromide | 1.14 |
| IX-2 | Tetrabutylammonium bromide | 1.14 |
| IX-3 | Tetrabutylammonium p-toluene sulfonate | 1.14 |
| IX-4 | Triphenylphosphine | 1.14 |
| IX-5 | Benzyldimethylamine | 1.14 |

In Table 2, the catalyst used for the synthesis of Polymer (I-1), Polymer (I-2), and Polymer (I-4) to Polymer (I-7) is an ammonium carboxylic acid salt. Furthermore, in Table 2, the catalyst used for the synthesis of Polymer (I-3) is a zwitterion having an ammonium group and a carboxylate group in the molecule.

[Synthesis of Polymer (II)]

Under a nitrogen gas stream, a solution (so-called monomer solution) obtained by dissolving cyclohexyl methacrylate (19.3 g), methyl methacrylate (0.46 g), and methacrylic acid (8.9 g) in propylene glycol monomethyl ether acetate (10 g), and a solution (so-called polymerization initiator solution) obtained by dissolving V-601 (manufactured by FUJIFILM Wako Pure Chemical Corporation, 0.92 g) as a polymerization initiator in propylene glycol monomethyl ether acetate (11.4 g) were added dropwise to a solution of propylene glycol monomethyl ether (20 g) and propylene glycol monomethyl ether acetate (5 g) heated to 90° C., for 3 hours using different dripping pumps. Next, the mixture was caused to react at 90° C. for 1 hour, and then 0.2 g each of V-601 was added thereto three times at an interval of 1 hour. Next, the mixture was caused to react at 90° C. for another 3 hours, and then the mixture was diluted with propylene glycol monomethyl ether acetate (14.9 g) to obtain a polymer solution. To the obtained polymer solution, glycidyl methacrylate (trade name: BLEMMER GH, manufactured by NOF Corporation, 6.3 g), which is a polymerizable compound having a cyclic ether group, tetrabutylammonium acetate (manufactured by Tokyo Chemical Industry Co., Ltd., 0.33 g), which is an ammonium carboxylic acid salt, as a catalyst, and p-methoxyphenol (0.07 g) were added and mixed, and the mixture was caused to react at 100° C. for 7 hours under an air stream to obtain a solution including Polymer (II). Propylene glycol monomethyl ether acetate was added to the obtained solution including Polymer (II) to obtain a polymer solution having a solid content concentration of 27% by mass. The residual amount of glycidyl methacrylate in this polymer solution was measured by gas chromatography (GC), and the residual amount was 0.1% by mass or less. The weight-average molecular weight of the obtained polymer was 22,000, and the dispersity was 2.2. The dispersity was measured by GPC in the same manner as in the case of the weight-average molecular weight. The acid value of the polymer determined by the above-described Formula X was 96 mgKOH/g.

[Synthesis of Polymer (III)]

Under a nitrogen gas stream, a solution (so-called monomer solution) obtained by dissolving styrene (172 g), methyl methacrylate (4.7 g), and methacrylic acid (112.1 g) in propylene glycol monomethyl ether (30 g), and a solution (so-called polymerization initiator solution) obtained by dissolving V-601 (manufactured by FUJIFILM Wako Pure Chemical Corporation, 27.6 g) as a polymerization initiator in propylene glycol monomethyl ether (57.7 g) were added dropwise to a solution of propylene glycol monomethyl ether (113.5 g) heated to 90° C., for 3 hours using different dripping pumps. After completion of the dropping, 2.5 g each of V-601 was added three times at an interval of 1 hour. Next, the mixture was caused to react for another 3 hours at 90° C., and then the mixture was diluted with propylene glycol monomethyl ether acetate (160.7 g) and propylene glycol monomethyl ether (233.3 g) to obtain a polymer solution. The temperature of the polymer solution was raised to 100° C. under an air stream. Next, to this polymer solution, tetrabutylammonium acetate (5.2 g), which is an ammonium carboxylic acid salt, as a catalyst, and p-methoxyphenol (0.86 g) were added, subsequently glycidyl methacrylate (trade name: BLEMMER GH, manufactured by NOF Corporation, 71.9 g), which is a polymerizable compound having a cyclic ether group, was added dropwise thereto for 20 minutes, and the mixture was caused to react at 100° C. for 7 hours to obtain a solution including Polymer (III). Propylene glycol monomethyl ether acetate was added to the obtained solution including Polymer (III) to obtain a polymer solution having a solid content concentration of 27% by mass. The amount of monomers remaining in this polymer solution (so-called residual monomers) was measured by gas chromatography (GC), and the amount was 0.1% by mass with respect to the total solid content mass of the polymer solution for all of the monomers. The weight-average molecular weight of the obtained polymer was 17,000, and the dispersity was 2.4. The dispersity was measured by GPC in the same manner as in the case of the weight-average molecular weight. The acid value of the polymer determined by the above-described Formula X was 124 mgKOH/g.

[Synthesis of Polymer (IV) to Polymer (VI)]

Solutions respectively including Polymer (IV) to Polymer (VI) were obtained by procedures similar to the case of Polymer (III), except that raw materials having the compositions shown below were used. The solid content concentration of each of the polymer solutions is 27% by mass. For each of the polymer solutions, the amount of monomers remaining in the polymer solution (so-called residual monomers) was measured by gas chromatography (GC), and the amount was 0.1% by mass or less with respect to the total solid content mass of the polymer solution for all of the monomers.

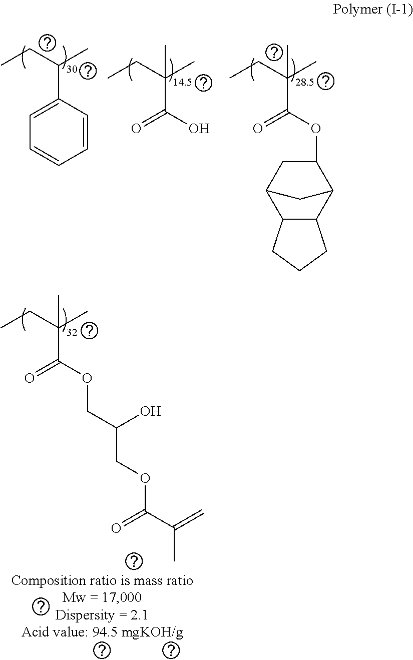

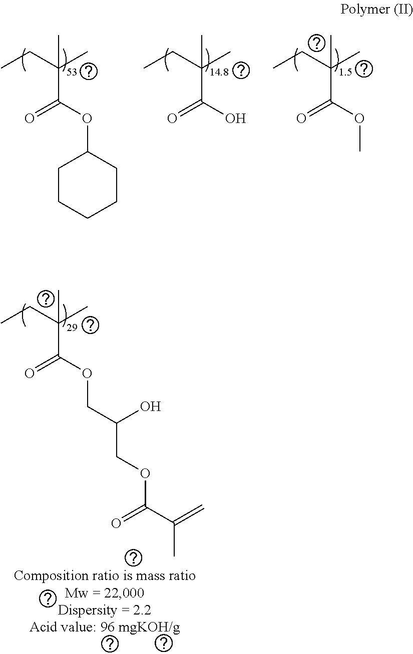

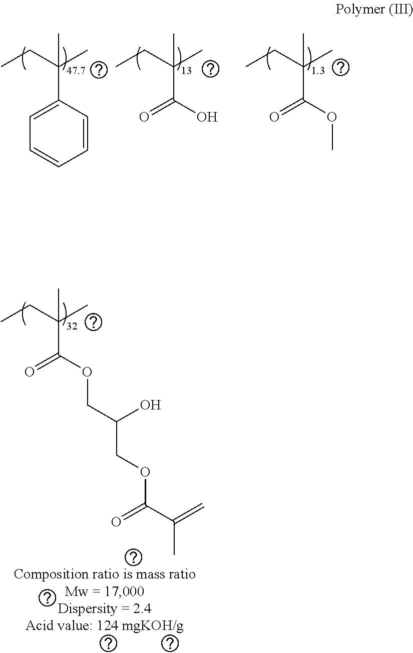

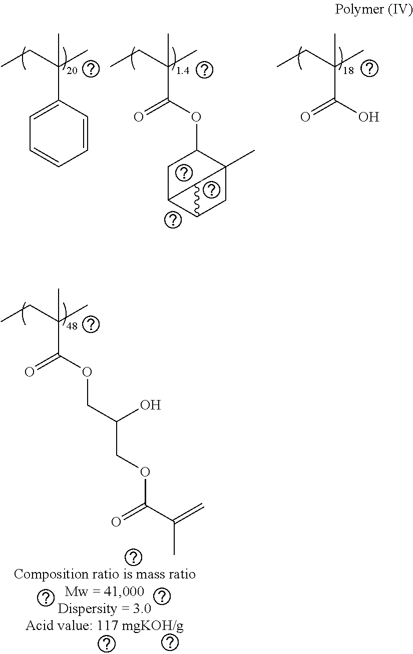

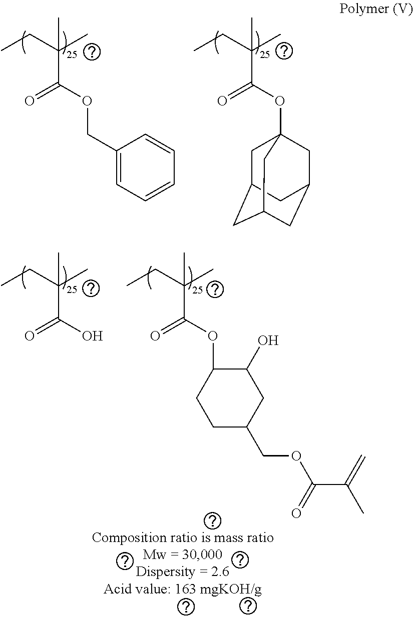

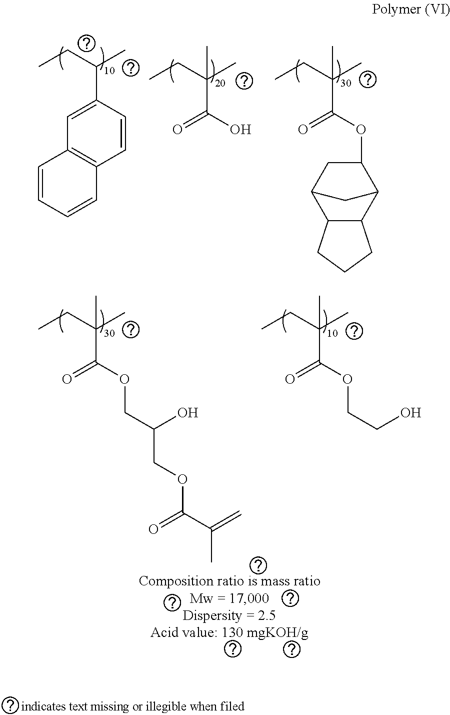

[Preparation of Negative Tone Photosensitive Composition]

Negative tone photosensitive compositions A1 to A18 having the compositions shown in the following Table 3 and negative tone photosensitive compositions AX1 to AX5 having the compositions shown in the following Table 4 were respectively prepared. Unless particularly stated otherwise, the unit of the numerical value described in the column of each component in Table 3 and Table 4 is parts by mass. The halogen ion content of each of the negative tone photosensitive compositions was measured by an ion chromatography method, and the total halogen ion content in the negative tone photosensitive compositions A1 to A18 and AX3 to AX5 was 1 ppm or less. The total halogen ion content in the negative tone photosensitive compositions AX1 and AX2 was 100 ppm to 200 ppm.

### Examples 1 to 18 and Comparative Examples 1 to 5

A negative tone photosensitive composition selected according to the description of the following Table 3 or Table 4 was applied, using a slit-shaped nozzle, on the surface of a protective layer (trade name: CERAPEEL (registered trademark) 25WZ, thickness: 25 μm, manufactured by Toray Advanced Film Co., Ltd., polyethylene terephthalate film with release layer) where a release layer was formed, subsequently the solvent was volatilized in a drying zone at 120° C., and thereby a photosensitive layer having a thickness of 8 μm was formed. The composition for an antistatic layer (B-1) was applied on the photosensitive layer using a slit-shaped nozzle and was subsequently dried, and thus an antistatic layer having a thickness of 0.1 μm was formed. Next, a temporary support (trade name: LUMIRROR 16QS62, thickness: 16 μm, manufactured by Toray Industries, Inc., polyethylene terephthalate film) was pressure-bonded onto the antistatic layer. Transfer films of Examples 1 to 18 and Comparative Examples 1 to 5 were respectively produced by the above-described procedure. Each of the transfer films has a protective layer, a photosensitive layer, an antistatic layer, and a temporary support in this order.

[Evaluation]

(Change in Resistance Value)

The protective layer was peeled off from each of the transfer films of Examples and Comparative Examples, subsequently the surface of the exposed photosensitive layer is laminated on a substrate (polyethylene terephthalate film) having a layer including a silver nanowire (so-called conductive layer), and thereby a structure having a laminated structure of temporary support/antistatic layer/photosensitive layer/layer including a silver nanowire/substrate was obtained. Hereinafter, the “layer including a silver nanowire/substrate” will be referred to as “silver nanowire substrate”. The lamination conditions for each transfer film were a roll temperature of 110° C., a linear pressure of 0.6 MPa, and a linear velocity (so-called lamination rate) of 2.0 m/min. Each of the above-described structures was exposed with i-line at an exposure amount of 120 mJ/cm² using a proximity type exposure machine (manufactured by Hitachi High-Tech Electronics Engineering Co., Ltd.) equipped with an ultrahigh-pressure mercury lamp, without peeling off the temporary support. The temporary support was peeled off, subsequently the structure was further exposed with i-line at an exposure amount of 375 mJ/cm², and then post-baking was performed at 145° C. for 30 minutes to cure the antistatic layer and the photosensitive layer. Through the above-described procedure, a laminated structure of a film obtained by curing the antistatic layer/a cured film of the photosensitive layer/a silver nanowire substrate was obtained. Each of the above-described laminated structures was cut into a square that measured 10 cm×10 cm. The resistance value of the layer including a silver nanowire (so-called sheet resistance value) in each of the laminated structures was measured using a non-contact resistance meter EC-80P (manufactured by Napson Corporation), and the average of the resistance values taken at nine sites in the plane was designated as initial resistance value of the laminated structure. Next, each of the laminated structures whose resistance value had been measured was left to stand in an environment at 85° C. and 85% RH (relative humidity) for 500 hours, and then the resistance value of each of the laminated structures was measured by a method similar to the method described above (hereinafter, referred to as “resistance value after durability test”). The rate of change in the resistance value was calculated based on the following formula.

Formula: Rate of change in resistance value (%)=([Resistance value after durability test]÷[initial resistance value]−1)×100

The rate of change in the obtained resistance value was evaluated according to the following criteria. The evaluation results are shown in Tables 3 and Table 4.

(Criteria)

A: The rate of change in the resistance value is 10% or less.

B: The rate of change in the resistance value is more than 10% and 20% or less.

C: The rate of change in the resistance value is more than 20% and 30% or less.

D: The rate of change in the resistance value is more than 30%.

(Transmittance after Baking)

The protective layer was peeled off from each of the transfer films of Examples and Comparative Examples, subsequently the surface of the exposed photosensitive layer was laminated on a glass substrate (trade name: Eagle XG, thickness: 0.7 mm, manufactured by Corning Inc.), and thereby a structure having a laminated structure of temporary support/antistatic layer/photosensitive layer/glass substrate was obtained. The lamination conditions for each transfer film were a roll temperature of 110° C., a linear pressure of 0.6 MPa, and a linear velocity (so-called lamination rate) of 2.0 m/min. Each of the above-described structures was exposed with i-line at an exposure amount of 120 mJ/cm² using a proximity type exposure machine (manufactured by Hitachi High-Tech Electronics Engineering Co., Ltd.) equipped with an ultrahigh-pressure mercury lamp, without peeling off the temporary support. The temporary support was peeled off, subsequently the structure was further exposed with i-line at an exposure amount of 375 mJ/cm², and then post-baking was performed at 145° C. for 30 minutes to cure the antistatic layer and the photosensitive layer. Through the above-described procedure, a laminated structure of a film obtained by curing the antistatic layer/a cured film of the photosensitive layer/a glass substrate was obtained. The transmittance of the laminated structure at a wavelength of 400 nm to 800 nm was measured using an ultraviolet-visible spectrophotometer (product name: UV-1800, manufactured by Shimadzu Corporation) and using a glass substrate as a reference, and the average transmittance was determined. The obtained average transmittance was evaluated according to the following criteria. The evaluation results are shown in Tables 3 and Table 4.

(Criteria)

A: The average transmittance at a wavelength of 400 to 800 nm is 90% or higher.

B: The average transmittance at a wavelength of 400 to 800 nm is 85% or higher and lower than 90%.

C: The average transmittance at a wavelength of 400 to 800 nm is 80% or higher and lower than 85%.

D: The average transmittance at a wavelength of 400 to 800 nm is lower than 80%.

TABLE 3

| | | Example | | | | | | | | |
|---|---|---|---|---|---|---|---|---|---|---|
| | | 1 | 2 | 3 | 4 | 5 | 6 | 7 | 8 | 9 |
| Negative tone photosensitive composition | | A1 | A2 | A3 | A4 | A5 | A6 | A7 | A8 | A9 |
| Polymer | Polymer solution | I-1 | I-2 | I-3 | I-4 | II | I-1 | I-5 | I-5 | I-6 |
| | (Solid content | 29.29 | 29.29 | 29.29 | 29.29 | 29.29 | 29.29 | 14 | 29.29 | 15 |
| | concentration: 27% | | | | | | | | | |
| | by mass) | | | | | | | | | |
| Polymerizable | A-DOD-N | 3.16 | 3.16 | 3.16 | 3.16 | 3.16 | — | — | 3.16 | — |
| monomer | DPHA | 4.16 | 4.16 | 4.16 | 4.16 | 4.16 | — | 11 | 4.16 | — |
| | DTPA | — | — | — | — | — | 4.16 | — | — | 10 |
| | A-DCP | — | — | — | — | — | 3.16 | — | — | — |
| Photopolymerization | IRGACURE | 0.07 | 0.07 | 0.07 | 0.07 | 0.07 | 0.07 | 0.07 | 0.07 | 0.07 |
| initiator | OXE-02 | | | | | | | | | |
| | Omnirad | 0.15 | 0.15 | 0.15 | 0.15 | 0.15 | 0.15 | 0.15 | 0.15 | 0.15 |
| | 907 | | | | | | | | | |
| | Lucirin | — | — | — | — | — | — | — | — | — |
| | TPO | | | | | | | | | |
| Surfactant | Megaface | 0.05 | 0.05 | 0.05 | 0.05 | 0.05 | 0.05 | 0.05 | 0.05 | 0.05 |
| | F551A | | | | | | | | | |
| | DOWSIL8032 | — | — | — | — | — | — | — | — | — |
| | Additive | | | | | | | | | |
| Solvent | PGMEA | 37.36 | 37.36 | 37.36 | 37.36 | 37.36 | 37.36 | 37.36 | 37.36 | 37.36 |
| | MEK | 25.65 | 25.65 | 25.65 | 25.65 | 25.65 | 25.65 | 25.65 | 25.65 | 25.65 |
| Content of specific ammonium compound | | 0.42 | 0.42 | 0.42 | 0.42 | 0.45 | 0.43 | 0.1 | 0.21 | 1.0 |
| in total solid content (% by mass) | | | | | | | | | | |
| Evaluation | Change in resistance | A | A | A | B | A | A | B | A | A |
| | value | | | | | | | | | |
| | Transmittance after | A | A | A | A | A | A | A | A | A |
| | baking | | | | | | | | | |
| | | Example | | | | | | | | |
| | | 10 | 11 | 12 | 13 | 14 | 15 | 16 | 17 | 18 |
| Negative tone photosensitive composition | | A10 | A11 | A12 | A13 | A14 | A15 | A16 | A17 | A18 |
| Polymer | Polymer solution | I-6 | I-7 | I-7 | I-1 | III | IV | V | VI | I-1 |
| | (Solid content | 29.29 | 29.29 | 36 | 29.29 | 29.29 | 29.29 | 29.29 | 29.29 | 29.29 |
| | concentration: 27% | | | | | | | | | |
| | by mass) | | | | | | | | | |
| Polymerizable | A-DOD-N | 3.5 | 2 | — | 3.16 | 3.16 | 3.16 | 3.16 | 3.16 | 3.16 |
| monomer | DPHA | 2 | 2 | — | 4.16 | 4.16 | 4.16 | 4.16 | 4.16 | 4.16 |
| | DTPA | — | 2.6 | — | — | — | — | — | — | — |
| | A-DCP | — | — | 4.4 | — | — | — | — | — | — |
| Photopolymerization | IRGACURE | 0.07 | 0.07 | 0.07 | — | 0.07 | 0.07 | 0.07 | 0.07 | 0.07 |
| initiator | OXE-02 | | | | | | | | | |
| | Omnirad | 0.15 | 0.15 | 0.15 | — | 0.15 | 0.15 | 0.15 | 0.15 | 0.15 |
| | 907 | | | | | | | | | |
| | Lucirin | — | — | — | 2 | — | — | — | — | — |
| | TPO | | | | | | | | | |
| Surfactant | Megaface | 0.05 | 0.05 | 0.05 | 0.05 | 0.05 | 0.05 | 0.05 | 0.05 | — |
| | F551A | | | | | | | | | |
| | DOWSIL8032 | — | — | — | — | — | — | — | — | 0.02 |
| | Additive | | | | | | | | | |
| Solvent | PGMEA | 37.36 | 39 | 37.36 | 37.36 | 37.36 | 37.36 | 37.36 | 37.36 | 37.36 |
| | MEK | 25.65 | 24 | 25.65 | 25.65 | 25.65 | 25.65 | 25.65 | 25.65 | 25.65 |
| Content of specific ammonium compound | | 2.0 | 4.0 | 5.0 | 0.38 | 0.42 | 0.42 | 0.42 | 0.42 | 0.42 |
| in total solid content (% by mass) | | | | | | | | | | |
| Evaluation | Change in resistance | A | B | B | A | A | A | A | A | A |
| | value | | | | | | | | | |
| | Transmittance after | A | A | B | A | A | A | A | A | A |
| | baking | | | | | | | | | |

TABLE 4

| | | Comparative Example | | | | |
|---|---|---|---|---|---|---|
| | | 1 | 2 | 3 | 4 | 5 |
| Negative tone photosensitive composition | | AX1 | AX2 | AX3 | AX4 | AX5 |
| Polymer | Polymer solution | IX-1 | IX-2 | IX-3 | IX-4 | IX-5 |
| | (Solid content | 29.29 | 29.29 | 29.29 | 29.29 | 29.29 |
| | concentration: 27% by | | | | | |
| | mass) | | | | | |
| Polymerizable | A-DOD-N | 3.16 | 3.16 | 3.16 | 3.16 | 3.16 |
| monomer | DPHA | 4.16 | 4.16 | 4.16 | 4.16 | 4.16 |
| | DTPA | — | — | — | — | — |
| | A-DCP | — | — | — | — | — |
| Photopolymerization | IRGACURE | 0.07 | 0.07 | 0.07 | 0.07 | 0.07 |
| initiator | OXE-02 | | | | | |
| | Omnirad | 0.15 | 0.15 | 0.15 | 0.15 | 0.15 |
| | 907 | | | | | |
| | Lucirin | — | — | — | — | — |
| | TPO | | | | | |
| Surfactant | Megaface | 0.05 | 0.05 | 0.05 | 0.05 | 0.05 |
| | F551A | | | | | |
| | DOWSIL8032 | — | — | — | — | — |
| | Additive | | | | | |
| Solvent | PGMEA | 37.36 | 37.36 | 37.36 | 37.36 | 37.36 |
| | MEK | 25.65 | 25.65 | 25.65 | 25.65 | 25.65 |
| Content of specific ammonium compound in | | — | — | — | — | — |
| total solid content (% by mass) | | | | | | |
| Evaluation | Change in resistance | D | D | C | C | C |
| | value | | | | | |
| | Transmittance after | C | C | D | D | D |
| | baking | | | | | |

The following abbreviations shown in Table 3 and Table 4 have the following meanings, respectively.

“A-DOD-N”: 1,10-Decanediol diacrylate (manufactured by Shin-Nakamura Chemical Co., Ltd.)

“DPHA”: Dipentaerythritol tetraacrylate (manufactured by Nippon Kayaku Co., Ltd.) “DTPA”: Ditrimethylolpropane tetraacrylate (manufactured by Shin-Nakamura Chemical Co., Ltd.)

“A-DCP”: Dicyclopentane dimethanol diacrylate (manufactured by Shin-Nakamura Chemical Co., Ltd.)

“PGMEA”: Propylene glycol monomethyl ether acetate “MEK”: Methyl ethyl ketone

“IRGACURE OXE-02” shown in Table 3 and Table 4 is a photopolymerization initiator manufactured by BASF SE. Furthermore, “Omnirad 907” and “Lucirin TPO” shown in Table 3 and Table 4 are both photopolymerization initiators manufactured by IGM Resins B.V.

“MEGAFACE F551A” shown in Table 3 and Table 4 is a fluorine-based surfactant manufactured by DIC Corporation. Furthermore, “DOWSIL 8032 Additive” shown in Table 3 and Table 4 is a silicone-based surfactant manufactured by DuPont Toray Specialty Materials K.K.

The “specific ammonium compound” shown in Table 3 and Table 4 is a generic term for an ammonium carboxylic acid salt and a zwitterion having an ammonium group and a carboxylate group in the molecule.

As shown in Table 3 and Table 4, in Examples 1 to 18, the changes in the resistance value before and after a durability test were small as compared with Comparative Examples 1 to 5. The above-described results show that in Examples 1 to 18, an increase in the resistance value of the layer including a silver nanowire (so-called conductive layer) could be suppressed. Furthermore, it was found that Examples 1 to 18 had superior transparency because a decrease in transmittance due to a baking treatment was suppressed as compared with Comparative Examples 1 to 5.

### Examples 101 to 113 and Comparative Examples 101 to 105

A negative tone photosensitive composition selected according to the description in the following Table 5 was applied on a temporary support (trade name: LUMIRROR 16QS62, thickness: 16 μm, manufactured by Toray Industries, Inc., polyethylene terephthalate film) using a slit-shaped nozzle, subsequently the solvent was volatilized in a drying zone at 120° C., and thereby a photosensitive layer having a thickness of 5 μm was formed. Next, a protective layer (trade name: CERAPEEL (registered trademark) 25WZ, thickness: 25 μm, manufactured by Toray Advanced Film Co., Ltd., polyethylene terephthalate film with release layer) was pressure-bonded to the photosensitive layer such that the surface where the release layer was formed was pressure-bonded to the photosensitive layer. Through the above-described procedure, transfer films of Examples 101 to 113 and Comparative Examples 101 to 105 were respectively produced. Each of the above-described transfer films had a protective layer, a photosensitive layer, and a temporary support in this order.

[Evaluation]

Evaluations were carried out in the same manner as in Example 1 using the transfer films of Examples 101 to 113 and Comparative Examples 101 to 105. The evaluation results are presented in Table 5.

TABLE 5

| | | Example | | | | | | | | |
|---|---|---|---|---|---|---|---|---|---|---|
| | | 101 | 102 | 103 | 104 | 105 | 106 | 107 | 108 | 109 |
| Negative tone photosensitive | | A1 | A2 | A3 | A4 | A5 | A6 | A7 | A8 | A9 |
| composition | | | | | | | | | | |
| Polymer | Polymer solution | I-1 | I-2 | I-3 | I-4 | II | I-1 | I-5 | I-5 | 1-6 |
| | (Solid content | 29.29 | 29.29 | 29.29 | 29.29 | 29.29 | 29.29 | 14 | 29.29 | 15 |
| | concentration: | | | | | | | | | |
| | 27% by mass) | | | | | | | | | |
| Polymerizable | A-DOD-N | 3.16 | 3.16 | 3.16 | 3.16 | 3.16 | — | — | 3.16 | — |
| monomer | DPHA | 4.16 | 4.16 | 4.16 | 4.16 | 4.16 | — | 11 | 4.16 | — |
| | DTPA | — | — | — | — | — | 4.16 | — | — | 10 |
| | A-DCP | — | — | — | — | — | 3.16 | — | — | — |
| Photopolymerization | IRGACURE | 0.07 | 0.07 | 0.07 | 0.07 | 0.07 | 0.07 | 0.07 | 0.07 | 0.07 |
| initiator | OXE-02 | | | | | | | | | |
| | Omnirad | 0.15 | 0.15 | 0.15 | 0.15 | 0.15 | 0.15 | 0.15 | 0.15 | 0.15 |
| | 907 | | | | | | | | | |
| | Lucirin | — | — | — | — | — | — | — | — | — |
| | TPO | | | | | | | | | |
| Surfactant | Megafac | 0.05 | 0.05 | 0.05 | 0.05 | 0.05 | 0.05 | 0.05 | 0.05 | 0.05 |
| | F551A | | | | | | | | | |
| Solvent | PGMEA | 37.36 | 37.36 | 37.36 | 37.36 | 37.36 | 37.36 | 37.36 | 37.36 | 37.36 |
| | MEK | 25.65 | 25.65 | 25.65 | 25.65 | 25.65 | 25.65 | 25.65 | 25.65 | 25.65 |
| Content of specific ammonium | | 0.42 | 0.42 | 0.42 | 0.42 | 0.45 | 0.43 | 0.1 | 0.21 | 1.0 |
| compound in total solid content (% by | | | | | | | | | | |
| mass) | | | | | | | | | | |
| Evaluation | Change in | A | A | A | B | A | A | B | A | A |
| | resistance value | | | | | | | | | |
| | Transmittance | A | A | A | A | A | A | A | A | A |
| | after baking | | | | | | | | | |
| | | Example | | | | Comparative Example | | | | |
| | | 110 | 111 | 112 | 113 | 101 | 102 | 103 | 104 | 105 |
| Negative tone photosensitive | | A10 | A11 | A12 | A13 | AX1 | AX2 | AX3 | AX4 | AX5 |
| composition | | | | | | | | | | |
| Polymer | Polymer solution | I-6 | I-7 | I-7 | I-1 | IX-1 | IX-2 | IX-3 | IX-4 | IX-5 |
| | (Solid content | 29.29 | 29.29 | 36 | 29.29 | 29.29 | 29.29 | 29.29 | 29.29 | 29.29 |
| | concentration: | | | | | | | | | |
| | 27% by mass) | | | | | | | | | |
| Polymerizable | A-DOD-N | 3.5 | 2 | — | 3.16 | 3.16 | 3.16 | 3.16 | 3.16 | 3.16 |
| monomer | DPHA | 2 | 2 | — | 4.16 | 4.16 | 4.16 | 4.16 | 4.16 | 4.16 |
| | DTPA | — | 2.6 | — | — | — | — | — | — | — |
| | A-DCP | — | — | 4.4 | — | — | — | — | — | — |
| Photopolymerization | IRGACURE | 0.07 | 0.07 | 0.07 | — | 0.07 | 0.07 | 0.07 | 0.07 | 0.07 |
| initiator | OXE-02 | | | | | | | | | |
| | Omnirad | 0.15 | 0.15 | 0.15 | — | 0.15 | 0.15 | 0.15 | 0.15 | 0.15 |
| | 907 | | | | | | | | | |
| | Lucirin | — | — | — | 2 | — | — | — | — | — |
| | TPO | | | | | | | | | |
| Surfactant | Megafac | 0.05 | 0.05 | 0.05 | 0.05 | 0.05 | 0.05 | 0.05 | 0.05 | 0.05 |
| | F551A | | | | | | | | | |
| Solvent | PGMEA | 37.36 | 39 | 37.36 | 37.36 | 37.36 | 37.36 | 37.36 | 37.36 | 37.36 |
| | MEK | 25.65 | 24 | 25.65 | 25.65 | 25.65 | 25.65 | 25.65 | 25.65 | 25.65 |
| Content of specific ammonium | | 2.0 | 4.0 | 5.0 | 0.38 | — | — | — | — | — |
| compound in total solid content (% by | | | | | | | | | | |
| mass) | | | | | | | | | | |
| Evaluation | Change in | A | B | B | A | D | D | C | C | C |
| | resistance value | | | | | | | | | |
| | Transmittance | A | A | B | A | C | C | D | D | D |
| | after baking | | | | | | | | | |

In Table 5, the same terms as those described in Table 3 and Table 4 have the same meanings as the terms described in Table 3 and Table 4.

According to the results shown in Table 5, it was made clear that in Examples 101 to 113, an increase in the resistance value of a layer including a silver nanowire (so-called conductive layer) can be suppressed, as compared with Comparative Examples 101 to 105. Furthermore, it was found that in Examples 101 to 113, a decrease in transmittance due to a baking treatment is suppressed, and transparency is superior, as compared with Comparative Examples 101 to 105.

The disclosure of JP2019-176902, filed Sep. 27, 2019, is incorporated herein by reference in its entirety.

All documents, patent applications, and technical standards described herein are incorporated herein by reference to the same extent as if each individual document, patent application, and technical standard were specifically and individually stated to be incorporated by reference.

What is claimed is:

1. A photosensitive composition comprising:
a polymer having a polymerizable functional group in a side chain; and
an ammonium compound containing an ammonium cation and a carboxylate anion.

2. The photosensitive composition according to claim 1,
wherein the photosensitive composition is a negative photosensitive composition.

3. The photosensitive composition according to claim 1,
wherein a content of the ammonium compound is 0.01% by mass to 5% by mass with respect to a total solid content mass of the photosensitive composition.

4. The photosensitive composition according to claim 1,
wherein the ammonium compound is at least one ammonium compound selected from the group consisting of an ammonium carboxylic acid salt and a zwitterion having an ammonium group and a carboxylate group in a molecule.

5. The photosensitive composition according to claim 1,
wherein the ammonium compound is an ammonium carboxylic acid salt.

6. The photosensitive composition according to claim 5,
wherein the ammonium carboxylic acid salt is a tetraalkylammonium carboxylic acid salt.

7. The photosensitive composition according to claim 1,
wherein the ammonium compound is a zwitterion having an ammonium group and a carboxylate group in a molecule.

8. The photosensitive composition according to claim 7,
wherein the zwitterion is a zwitterion having a trialkylammonium group and a carboxylate group in the molecule.

9. The photosensitive composition according to claim 1,
wherein the polymer has at least one group selected from the group consisting of an aliphatic cyclic hydrocarbon group and an aromatic group.

10. The photosensitive composition according to claim 1,
wherein the polymer is a polymer obtained by reacting a polymer having a carboxy group with a polymerizable compound having a cyclic ether group in the presence of an ammonium compound containing an ammonium cation and a carboxylate anion.

11. The photosensitive composition according to claim 1, further comprising a polymerizable monomer.

12. The photosensitive composition according to claim 1, further comprising a photopolymerization initiator.

13. The photosensitive composition according to claim 1,
wherein the photosensitive composition is used for a protective film of a silver conductive material.

14. A transfer film comprising:
a temporary support; and
a layer containing the photosensitive composition according to claim 1.

15. A cured film of the photosensitive composition according to claim 1.

16. A laminate comprising:
a substrate;
a layer containing a silver nanowire; and
a cured film of the photosensitive composition according to claim 1.

17. A touch panel comprising the laminate according to claim 16.

18. A method for producing a polymer having a polymerizable functional group in a side chain, the method comprising:
reacting a polymer having a carboxy group with a polymerizable compound having a cyclic ether group in the presence of an ammonium compound containing an ammonium cation and a carboxylate anion, to form a polymer having a polymerizable functional group in a side chain.

19. A method for producing the photosensitive composition according to claim 1, the method comprising:
reacting a polymer having a carboxy group with a polymerizable compound having a cyclic ether group in the presence of an ammonium compound containing an ammonium cation and a carboxylate anion, to form the polymer having a polymerizable functional group in a side chain.
